(19) United States
(12) Patent Application Publication
(10) Pub. No.: US 2026/0026138 A1
(43) Pub. Date: Jan. 22, 2026

(54) DISPLAY DEVICE AND ELECTRONIC DEVICE INCLUDING THE SAME

(71) Applicant: Samsung Display Co., LTD., Yongin-si (KR)

(72) Inventors: Hyung Rae CHA, Yongin-si (KR); Jong Hyuk KANG, Yongin-si (KR); Dae Hyun KIM, Yongin-si (KR); Chul Jong YOO, Yongin-si (KR)

(21) Appl. No.: 19/062,615

(22) Filed: Feb. 25, 2025

(30) Foreign Application Priority Data
Jul. 18, 2024 (KR) 10-2024-0094950

(51) Int. Cl. H10H 20/821; B60K 35/22; G02B 27/01; H10H 20/825; H10H 29/80

(52) U.S. Cl. CPC H10H 20/821; H10H 20/825; H10H 29/832; B60K 35/22; B60K 2360/774; G02B 27/0172; G02B 2027/0178

(57) ABSTRACT

A display device includes a lower substrate, a first electrode disposed on the lower substrate, a first light-emitting element disposed on the first electrode, a second electrode disposed on the first light-emitting element, and a second light-emitting element disposed on the second electrode. The first light-emitting element includes a first sidewall and a first bottom surface and the second light-emitting element includes a second sidewall and a second bottom surface. An angle between the first sidewall and the first bottom surface is different from an angle between the second sidewall and the second bottom surface.

This application claims priority to Korean Patent Application No. 10-2024-0094950, filed on Jul. 18, 2024, and all the benefits accruing therefrom under 35 U.S.C. § 119, the content of which in its entirety is herein incorporated by reference.

### BACKGROUND

### 1. Field

Embodiments of the disclosure relate to a display device and an electronic device including the same.

### 2. Description of the Related Art

With the advance of information-oriented society, more and more demands are placed on display devices for displaying images in various ways. Along with this trend, various types of display devices including a light-emitting display device are being developed. The light-emitting display device includes pixels including light-emitting elements.

### SUMMARY

Features of the disclosure provide a display device capable of improving the efficiency of light-emitting elements, and an electronic device including the same.

However, features of the disclosure are not restricted to the one set forth herein. The above and other features of the disclosure will become more apparent to one of ordinary skill in the art to which the disclosure pertains by referencing the detailed description of the disclosure given below.

In an embodiment of the disclosure, there is provided a display device including, a lower substrate, a first electrode disposed on the lower substrate, a first light-emitting element disposed on the first electrode, a second electrode disposed on the first light-emitting element, and a second light-emitting element disposed on the second electrode. The first light-emitting element includes a first sidewall and a first bottom surface and the second light-emitting element includes a second sidewall and a second bottom surface. A first angle between the first sidewall and the first bottom surface is different from a second angle between the second sidewall and the second bottom surface.

In an embodiment, the first electrode, the first light-emitting element, the second electrode, and the second light-emitting element may overlap each other in a plan view.

In an embodiment, one of the first and second sidewalls may include an inclined sidewall having a taper angle, and a remaining (the other) one of the first and second sidewalls may include a vertical sidewall.

In an embodiment, one of the first and second angles between one of the first and second bottom surfaces and the one of the first and second sidewalls including the inclined sidewall may be less than 85° or greater than 95°, and a remaining one of the first and second angles between a remaining one of the first and second bottom surfaces and the remaining one of first and second sidewalls including the vertical sidewall may be in a range of 85° to 95°.

In an embodiment, the first light-emitting element may emit red light, and the second light-emitting element may emit blue light or green light.

In an embodiment, the first sidewall may include the inclined sidewall, and the second sidewall may include the vertical sidewall.

In an embodiment, the first light-emitting element and the second light-emitting element may include first and second light-emitting layers including indium at different contents, respectively, and an indium content of the light-emitting layer of the first light-emitting element may be higher than an indium content of the light-emitting layer of the second light-emitting element.

In an embodiment, the first sidewall may include the inclined sidewall, and the second sidewall may include the vertical sidewall.

In an embodiment, in a plan view, one of the first and second light-emitting elements including the one of the first and second sidewalls inclined sidewall may be larger than a remaining one of the first and second light-emitting elements including the remaining one of the first and second sidewalls the light-emitting element including the vertical sidewall.

In an embodiment, the display device may further include a third electrode disposed between the first light-emitting element and the second electrode, and a third light-emitting element disposed on the third electrode and disposed between the first light-emitting element and the second light-emitting element.

In an embodiment, the third light-emitting element may include a third sidewall having a third angle equal to the first angle or the second angle.

In an embodiment, the first angle defined between the first bottom surface and the first sidewall of the first light-emitting element, the second angle defined between the second bottom surface and the second sidewall of the second light-emitting element, and a third angle defined between a third bottom surface and a third sidewall of the third light-emitting element may be different from each other.

In an embodiment, the third angle may have a value between the first angle and the second angle.

In an embodiment, the first light-emitting element, the second light-emitting element, and the third light-emitting element may overlap each other in a plan view.

In an embodiment of the disclosure, there is provided a display device including, a lower substrate, and a plurality of light-emitting elements disposed on the lower substrate and overlapping each other in a plan view. The plurality of light-emitting elements includes a first light-emitting element including a first sidewall and a first bottom surface and a second light-emitting element including a second sidewall and a second bottom surface. A first angle between the first sidewall and the first bottom surface is different from a second angle between the second sidewall and the second bottom surface.

In an embodiment, the first sidewall may include an inclined sidewall which is inclined at the first angle in a range of less than 85° or greater than 95° with respect to the first bottom surface of the first light-emitting element, and the second sidewall may include a vertical sidewall having the second angle in a range of 85° to 95° with respect to the second bottom surface of the second light-emitting element.

In an embodiment, the display device may further include a plurality of electrodes respectively disposed below the plurality of light-emitting elements and overlapping each other in a plan view.

In an embodiment, the display device may further include a plurality of pixel electrodes disposed between the lower substrate and the plurality of electrodes and individually connected to the plurality of electrodes, connection electrodes respectively disposed on top of the plurality of light-emitting elements, and a common electrode electrically connected to the connection electrodes.

In an embodiment, the first light-emitting element and the second light-emitting element may emit light of different colors.

In an embodiment, the first angle between the first bottom surface and the first sidewall of the first light-emitting element may be less than 85° or greater than 95°, and the second angle between the second bottom surface and the second sidewall of the second light-emitting element may be in a range of 85° to 95°.

In an embodiment of the disclosure, there is provided an electronic device including a display device. The display device may include a lower substrate, a first electrode disposed on the lower substrate, a first light-emitting element disposed on the first electrode, a second electrode disposed on the first light-emitting element, and a second light-emitting element disposed on the second electrode. The first light-emitting element includes a first sidewall and a first bottom surface and the second light-emitting element includes a second sidewall and a second bottom surface. An angle between the first sidewall and the first bottom surface is different from an angle between a second sidewall and the second bottom surface.

In the display device in embodiments, the efficiency of the light-emitting elements may be improved or optimized.

However, effects in the embodiments of the disclosure are not limited to those exemplified above and various other effects are incorporated herein.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view illustrating an embodiment of a display device;

FIG. 2 is a plan view illustrating an embodiment of a display area of a display device;

FIG. 3 is a plan view illustrating an embodiment of a display area of a display device;

FIG. 4 is a cross-sectional view illustrating an embodiment of a display device;

FIG. 5 is a cross-sectional view illustrating an embodiment of a display device;

FIG. 6 is a cross-sectional view showing an embodiment of a display device;

FIG. 7 is a cross-sectional view showing an embodiment of a display device;

FIG. 8 is a cross-sectional view showing an embodiment of a display device;

FIG. 9 is a cross-sectional view illustrating an embodiment of a display device;

FIG. 10 is a cross-sectional view showing an embodiment of a display device;

FIG. 11 is a cross-sectional view showing an embodiment of a display device;

FIGS. 12 to 16 are cross-sectional views illustrating an embodiment of a method of manufacturing a display device including light-emitting elements;

FIG. 17 is a diagram illustrating an embodiment of a smart watch including a display device;

FIGS. 18 and 19 illustrate an embodiment of a head mounted display including a display device;

FIG. 20 illustrates an embodiment of a head mounted display including a display device;

FIG. 21 is a diagram illustrating an embodiment of a dashboard of an automobile and a center fascia including display devices; and

FIG. 22 is a diagram illustrating an embodiment of a transparent display device including a display device.

### DETAILED DESCRIPTION

Embodiments of the disclosure will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer is referred to as being “on” another element or layer, it may be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Features of each of various embodiments of the disclosure may be partially or entirely combined with each other and may technically variously interwork with each other, and respective embodiments may be implemented independently of each other or may be implemented together in association with each other.

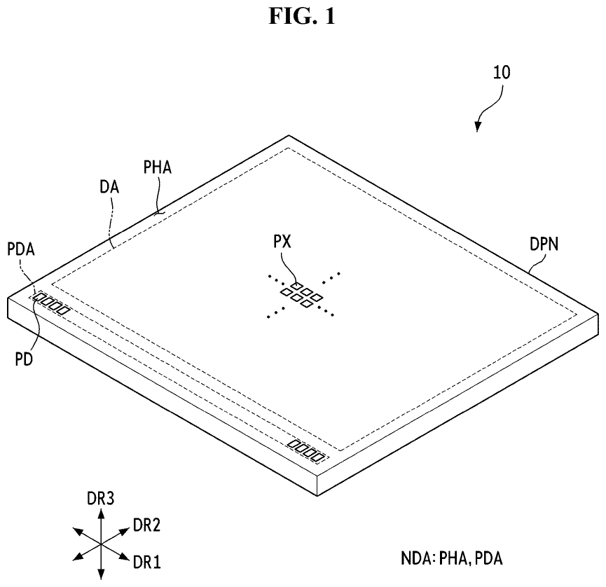

FIG. 1 is a perspective view illustrating an embodiment of a display device.

Referring to FIG. 1, a display device 10 is a device for displaying a moving image or a still image, and may be used as a display screen for various products. In an embodiment, the display device 10 may be used as a display screen for various products such as televisions, laptop computers, monitors, billboards and the Internet of Things (“IoT”) as well as portable electronic devices such as mobile phones, smart phones, tablet personal computers (tablet personal computer (“PCs”)), smart watches, watch phones, mobile communication terminals, electronic notebooks, electronic books, portable multimedia players (“PMPs”), navigation systems and ultra mobile PCs (“UMPCs”), for example. Additionally, the display device 10 may be applied to a virtual reality (“VR”) device, an augmented reality (“AR”) device, or the like.

In an embodiment, the display device 10 may be a light-emitting display device including light-emitting elements. In an embodiment, the display device 10 may be a light-emitting display device such as an organic light-emitting display including an organic light-emitting diode (“OLED”), a quantum dot light-emitting display including a quantum dot light-emitting layer, an inorganic light-emitting display including an inorganic semiconductor, or an ultra-small light-emitting display using an ultra-small light-emitting diode (ultra-small “LED”) such as a micro or nano light-emitting diode (“micro LED” or “nano LED”), for example.

Hereinafter, embodiments in which the display device 10 is a light-emitting display device including a micro or nano LED will be described. However, the type or size of the light-emitting element in embodiments is not limited thereto.

The display device 10 may include a display panel DPN including a display area DA and a non-display area NDA. In an embodiment, the display panel DPN may have a quadrilateral planar shape, but is not limited thereto. In an embodiment, the display panel DPN may have a polygonal shape other than a quadrilateral shape, a circular shape, an elliptical shape, or an irregular shape in a plan view, for example. In FIG. 1, a first direction DR1, a second direction DR2, and a third direction DR3 are indicated. In an embodiment, the first direction DR1, the second direction DR2, and the third direction DR3 may be the horizontal direction, the vertical direction, and the thickness direction of the display panel DPN, respectively.

The display area DA may be an area in which the pixels PX are disposed, and may be an area in which an image is displayed by the pixels PX. In an embodiment, the pixels PX and wires (or some of the wires) connected to the pixels PX may be disposed in the display area DA, for example. In describing embodiments, the term “connect” may include electrical connection and/or physical connection. Although FIG. 1 illustrates an embodiment in which the display area DA has a quadrilateral planar shape, the shape of the display area DA is not limited thereto.

The pixels PX may have a quadrilateral planar shape such as a quadrangular shape, e.g., rectangular shape or a rhombic shape, but the disclosure is not limited thereto. In an embodiment, the pixels PX may have another polygonal shape (e.g., a hexagonal shape or diamond shape), a circular shape, an elliptical shape, or other planar shapes, for example.

In an embodiment, each of the pixels PX of the display device 10 may include a plurality of light-emitting elements that emit light of different colors. In an embodiment, each pixel PX may include a first light-emitting element that emits light of a first color, a second light-emitting element that emits light of a second color, and a third light-emitting element that emits light of a third color, for example. In an embodiment, the light of the first color, the light of the second color, and the light of the third color may be red light, blue light, and green light, respectively, but are not limited thereto. The number, type, and/or arrangement structure of the light-emitting elements disposed in each pixel PX may be variously changed in other embodiments.

In an embodiment, each pixel PX may include a plurality of pixel circuits individually connected to the plurality of light-emitting elements. Accordingly, each of the light-emitting elements may be driven independently and/or individually. In an embodiment, each pixel PX may include a first pixel circuit electrically connected to the first light-emitting element, a second pixel circuit electrically connected to the second light-emitting element, and a third pixel circuit electrically connected to the third light-emitting element, for example. Accordingly, the light emission of the first light-emitting element, the second light-emitting element, and the third light-emitting element may be individually and/or independently controlled.

The non-display area NDA may be an area where an image is not displayed. The non-display area NDA may be disposed around the display area DA. In an embodiment, the non-display area NDA may be disposed at the edge of the display panel DPN to surround the display area DA.

The non-display area NDA may include a pad area PDA and a peripheral area PHA. Wires (or portions of the wires) connected to the pixels PX, and pads PD may be disposed in the non-display area NDA. In an embodiment, the non-display area NDA may further include a common voltage supply area disposed around the display area DA, e.g., between the display area DA and the pad area PDA.

The pads PD may be disposed in the pad area PDA. The pads PD may be connected to an external circuit board. In an embodiment, the pads PD may be electrically connected to circuit pads on the circuit board through a conductive connection member such as a wire. In addition, the pads PD may be electrically connected to the pixels PX, for example. In an embodiment, the pads PD may include signal pads and power pads that are electrically connected to the light-emitting elements and the pixel circuits of the pixels PX, for example. In an embodiment, the pixels PX and the pads PD may be electrically connected to each other through circuit elements and/or wires formed on a semiconductor circuit board or the like of the display panel DPN. Through the pads PD, driving signals and driving voltages for driving the pixels PX may be supplied from the external circuit board to the display device 10 (or the display panel DPN).

The peripheral area PHA may be the remaining area excluding the pad area PDA within the non-display area NDA. The peripheral area PHA may surround the display area DA. Wires that connect the pixels PX to the pads PD may pass through the peripheral area PHA.

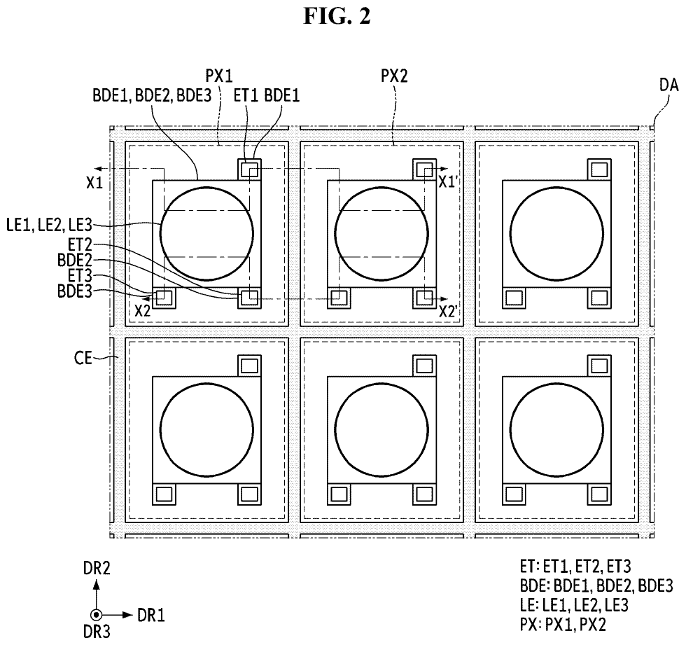

FIG. 2 is a plan view illustrating an embodiment of a display area of a display device. FIG. 2 schematically shows a part of the display area DA shown in FIG. 1, for example.

Referring to FIGS. 1 and 2, the plurality of pixels PX including a first pixel PX1 and a second pixel PX2 may be disposed in the display area DA. The pixels PX may be arranged in the display area DA in a matrix form, a stripe form, a Pentile™ form, or any other form.

The first pixel PX1 and the second pixel PX2 may refer to any two arbitrary pixels PX. In an embodiment, in FIG. 2, two pixels PX next (adjacent) to each other in the first direction DR1 are also referred to as the first pixel PX1 and the second pixel PX2, respectively, for example. The pixels PX of the display area DA may have substantially the same or similar structure, and may be independently and/or individually driven by driving signals supplied to the respective pixels PX.

In an embodiment, the pixels PX may have a quadrilateral planar shape such as a quadrangular shape, e.g., rectangular shape or a rhombic shape, but the disclosure is not limited thereto. In an embodiment, the pixels PX may have another polygonal shape (e.g., a hexagonal shape or diamond shape), a circular shape, an elliptical shape, or other planar shapes, for example.

Each pixel PX may include a plurality of light-emitting elements LE. In an embodiment, each pixel PX may include a first light-emitting element LE1, a second light-emitting element LE2, and a third light-emitting element LE3 that overlap each other in a plan view.

FIG. 2 illustrates the approximate positions or shapes of the first light-emitting element LE1, the second light-emitting element LE2, and the third light-emitting element LE3, and the disclosure is not limited to the illustrated form. In an embodiment, in FIG. 2, the first light-emitting element LE1, the second light-emitting element LE2, and the third light-emitting element LE3 are shown as having the same size and completely overlapping each other, for example, but the disclosure is not limited thereto. In an embodiment, in a plan view, the size of at least one of the first light-emitting element LE1, the second light-emitting element LE2, or the third light-emitting element LE3 may differ from the size of another.

The first light-emitting element LE1, the second light-emitting element LE2, and the third light-emitting element LE3 may emit light of different colors. In an embodiment, the first light-emitting element LE1 may be a red light-emitting element that emits light of the first color, e.g., red, for example. The second light-emitting element LE2 may be a blue light-emitting element that emits light of the second color, e.g., blue. The third light-emitting element LE3 may be a green light-emitting element that emits light of the third color, e.g., green. However, the disclosure is not limited thereto. In an embodiment, the number or type of the light-emitting elements LE disposed in each pixel PX may be variously changed, for example.

The light-emitting elements LE may have a circular shape, a quadrilateral shape, a polygonal shape other than a quadrilateral shape, or another planar shape. In an embodiment, FIG. 2 illustrates an embodiment in which the light-emitting elements LE have a circular planar shape, but the shape of the light-emitting elements LE may be variously changed, for example.

In an embodiment, the light-emitting elements LE may be micro LEDs having a relatively small size in the micrometer (μm) range. In an embodiment, each of the light-emitting elements LE may be a micro LED having a length (e.g., horizontal length or diameter) in the first direction DR1, a length (e.g., vertical length or diameter) in the second direction DR2, and a length (e.g., thickness or height) in the third direction DR3, which are several micrometers to several hundreds of micrometers, respectively, for example. In an embodiment, the length in the first direction DR1, the length in the second direction DR2, and the length in the third direction DR3 of each of the light-emitting elements LE may each be 100 μm or less. However, the disclosure is not limited thereto, and the size of the light-emitting elements LE may be variously changed.

Each pixel PX may further include a plurality of electrodes BDE electrically connected to the plurality of light-emitting elements LE. In an embodiment, each pixel PX may include the plurality of electrodes BDE individually connected to the plurality of light-emitting elements LE, and a plurality of pixel electrodes ET individually connected to the plurality of electrodes BDE, for example.

In an embodiment, the electrodes BDE may be single-layer or multi-layer bonding electrodes including or consisting of a conductive material suitable for bonding, but are not limited thereto. In an embodiment, the type, structure, or material of the electrodes BDE may vary in embodiments, for example.

In an embodiment, each pixel PX may include a first electrode BDE1, a second electrode BDE2, and a third electrode BDE3 that overlap each other in a plan view. The electrodes BDE may overlap the light-emitting elements LE. In an embodiment, the first electrode BDE1, the second electrode BDE2, and the third electrode BDE3 of the first pixel PX1 may overlap the first light-emitting element LE1, the second light-emitting element LE2, and the third light-emitting element LE3 of the first pixel PX1 in a plan view, for example. In an embodiment, the electrodes BDE may have a size larger than that of the light-emitting elements LE in a plan view, and may be disposed in an area that includes a region where the light-emitting elements LE are disposed and its surrounding region. The electrodes BDE may have the same shape as that of the light-emitting elements LE or may have a different shape from the light-emitting elements LE. FIG. 2 illustrates an embodiment in which the light-emitting elements LE have a circular planar shape and the electrodes BDE have a quadrilateral planar shape, but the shape of each of the light-emitting elements LE and the electrodes BDE may be variously changed in other embodiments.

In an embodiment, the first electrode BDE1, the second electrode BDE2, and the third electrode BDE3 may include or consist of the same material and/or structure, but the disclosure is not limited thereto. In an embodiment, at least two of the first electrode BDE1, the second electrode BDE2, and the third electrode BDE3 may include or consist of different materials and/or structures, for example.

In an embodiment, the electrodes BDE may have generally or substantially the same shape and/or size as each other, and may overlap each other in a region where the light-emitting elements LE are disposed. In an embodiment, the electrodes BDE may have substantially the same shape and/or size, except for the portions connected to the respective pixel electrodes ET, and may overlap each other in a plan view.

In an embodiment, the first electrode BDE1 may have a substantially quadrilateral planar shape and may protrude to overlap a first pixel electrode ET1 in a region where the first pixel electrode ET1 is disposed, for example. In a region where the first pixel electrode ET1 and the first electrode BDE1 overlap, the first pixel electrode ET1 and the first electrode BDE1 may be electrically connected to each other. The second electrode BDE2 may have a substantially quadrilateral planar shape and may protrude to overlap a second pixel electrode ET2 in a region where the second pixel electrode ET2 is disposed. In a region where the second pixel electrode ET2 and the second electrode BDE2 overlap, the second pixel electrode ET2 and the second electrode BDE2 may be electrically connected to each other. The third electrode BDE3 may have a substantially quadrilateral planar shape, and may protrude to overlap a third pixel electrode ET3 in a region where the third pixel electrode ET3 is disposed. In a region where the third pixel electrode ET3 and the third electrode BDE3 overlap, the third pixel electrode ET3 and the third electrode BDE3 may be electrically connected to each other.

The pixel electrodes ET may overlap the respective electrodes BDE, and may not overlap each other in a plan view. In an embodiment, the first pixel electrode ET1 may overlap a portion of the first electrode BDE1, for example. The second pixel electrode ET2 may overlap a portion of the second electrode BDE2. The third pixel electrode ET3 may overlap a portion of the third electrode BDE3. In an embodiment, the pixel electrodes ET may not overlap the light-emitting elements LE. In an embodiment, the pixel electrodes ET may be disposed around a region where the light-emitting elements LE are disposed, and may not overlap the light-emitting elements LE in a plan view. However, the disclosure is not limited thereto. The shape, position, or arrangement order of the pixel electrodes ET disposed in each pixel PX may be variously changed in other embodiments.

The pixel electrodes ET may be electrically connected to the light-emitting elements LE through the electrodes BDE. In an embodiment, the first pixel electrode ET1 may be electrically connected to the first light-emitting element LE1 through the first electrode BDE1, for example. The second pixel electrode ET2 may be electrically connected to the second light-emitting element LE2 through the second electrode BDE2. The third pixel electrode ET3 may be electrically connected to the third light-emitting element LE3 through the third electrode BDE3.

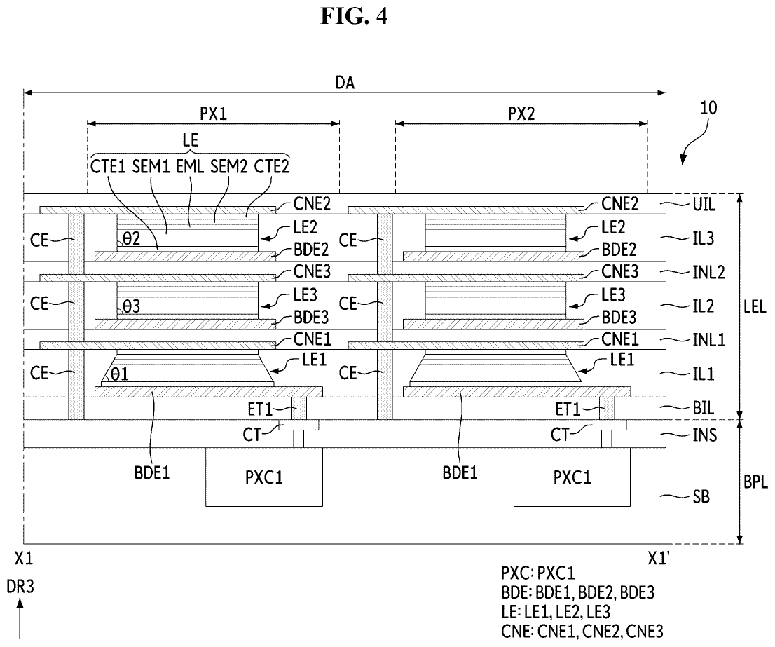

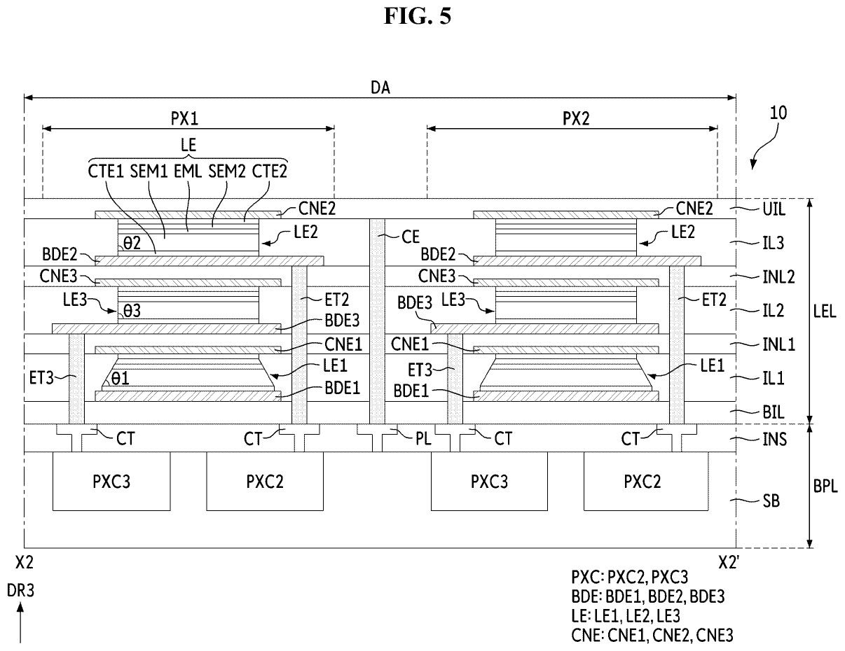

The pixel electrodes ET may be electrically connected to pixel circuits (e.g., pixel circuits PXC of FIGS. 4 and 5) of a lower substrate disposed below a light-emitting element layer including the light-emitting elements LE. In an embodiment, the pixel electrodes ET may electrically connect the light-emitting elements LE to the respective pixel circuits PXC, for example.

A common electrode CE (or a common voltage line) may be further disposed in the display area DA. In an embodiment, the common electrode CE defines openings corresponding to the pixels PX and may be disposed between the pixels PX. example, the common electrode CE may have a mesh shape surrounding the pixels PX in a plan view. However, the disclosure is not limited thereto. In an embodiment, the shape or position of the common electrode CE may be variously changed in other embodiments, for example.

In an embodiment, the common electrode CE may be electrically connected to the light-emitting elements LE through connection electrodes (e.g., connection electrodes CNE of FIGS. 4 and 5) that contact and/or connected to the light-emitting elements LE. However, the disclosure is not limited thereto. In an embodiment, the arrangement structure or connection structure of the common electrode CE and the light-emitting elements LE may be variously changed in other embodiments, for example.

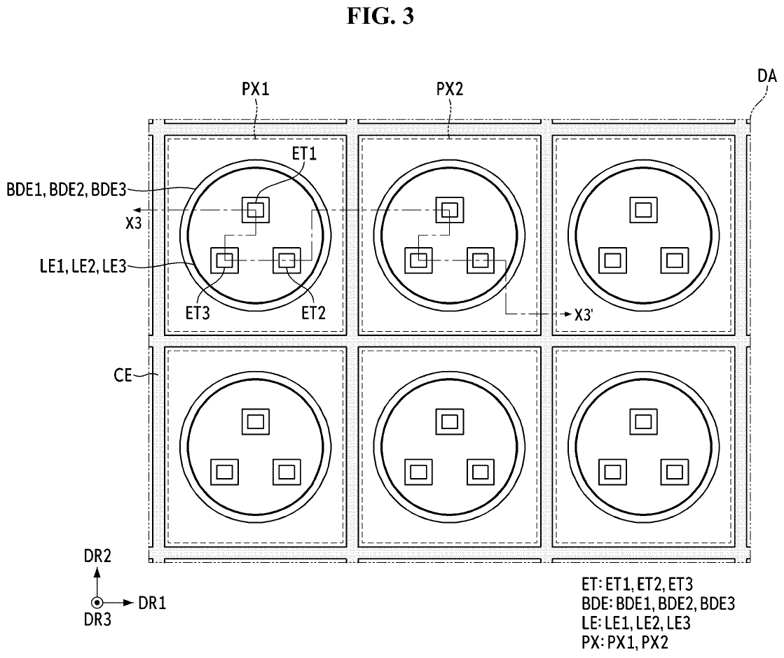

FIG. 3 is a plan view illustrating an embodiment of a display area of a display device. In an embodiment, FIG. 3 schematically shows a portion of the display area DA shown in FIG. 1, illustrating an embodiment of the display area DA different from the embodiment of FIG. 2, for example.

Referring to FIG. 3, the pixel electrodes ET may be disposed in the region where the light-emitting elements LE are disposed. Additionally, the pixel electrodes ET may overlap at least one electrode BDE and/or at least one light-emitting element LE.

In an embodiment, at least one (e.g., the electrodes BDE other than the electrode BDE disposed at the uppermost part) of the electrodes BDE may be opened in the region where the pixel electrodes ET, other than the pixel electrode ET electrically connected to the at least one electrode BDE, are disposed, so as to be insulated from remaining (the other) pixel electrodes ET. In an embodiment, the first electrode BDE1 may be opened to define an opening of a size larger than that of the second pixel electrode ET2 in the region where the second pixel electrode ET2 is disposed, for example. The second electrode BDE2 may not be opened in the region where the second pixel electrode ET2 is disposed, and may be electrically connected to the second pixel electrode ET2.

Similarly, at least one (e.g., the light-emitting elements LE other than the light-emitting element LE disposed at the uppermost part) of the light-emitting elements LE may be opened in the region where the pixel electrodes ET, other than the pixel electrode ET electrically connected to the at least one light-emitting element LE, are disposed, so as to be insulated from remaining (the other) pixel electrodes ET. In an embodiment, the first light-emitting element LE1 may be opened to define an opening of a size larger than that of the second pixel electrode ET2 in the region where the second pixel electrode ET2 is disposed, for example. The second light-emitting element LE2 may not be opened in the region where the second pixel electrode ET2 is disposed, and may be electrically connected to the second pixel electrode ET2 through the second electrode BDE2.

In the manner described above, the pixel electrodes ET may be disposed in the region where the light-emitting elements LE are disposed and be properly connected to the respective electrodes BDE and the respective light-emitting elements LE, while preventing short-circuit failures between the pixel electrodes ET and other electrodes BDE and/or the light-emitting elements LE. By disposing the pixel electrodes ET, the electrodes BDE, and the light-emitting elements LE to appropriately overlap, a pixel area where each pixel PX is disposed may be utilized more efficiently. In an embodiment, the electrodes BDE and/or the light-emitting elements LE having a larger size (e.g., a larger area) may be disposed in each pixel area, for example.

In an embodiment, the light-emitting elements LE and the electrodes BDE may have corresponding planar shapes. In an embodiment, the light-emitting elements LE and the electrodes BDE may have the same planar shape (e.g., a circular planar shape), for example. However, the disclosure is not limited thereto. In an embodiment, as in the embodiment of FIG. 2, the light-emitting elements LE and the electrodes BDE may have different planar shapes, for example.

In an embodiment, the light-emitting elements LE and the electrodes BDE may have different sizes in a plan view. In an embodiment, the electrodes BDE may have a size larger than that of the light-emitting elements LE in a plan view, for example. However, the disclosure is not limited thereto. In an embodiment, the light-emitting elements LE and the electrodes BDE may have the same size in a plan view, for example. In an embodiment, the light-emitting elements LE and the electrodes BDE may be formed to have substantially the same planar shape and/or size by etching the light-emitting elements LE and the electrodes BDE substantially simultaneously or consecutively by a single mask process using the same mask.

FIG. 4 is a cross-sectional view illustrating an embodiment of a display device. FIG. 5 is a cross-sectional view illustrating an embodiment of a display device. FIG. 4 shows an embodiment of a cross-section for a portion of the display area DA corresponding to line X1-X1′ in FIG. 2, and FIG. 5 shows an embodiment of a cross-section for a portion of the display area DA corresponding to line X2-X2′ in FIG. 2, for example.

Referring to FIGS. 4 and 5 in conjunction with FIGS. 1 and 2, the display device 10 may include a lower substrate BPL (or a thin film transistor substrate) and a light-emitting element layer LEL disposed on the lower substrate BPL. FIGS. 4 and 5 illustrate the display device 10 with an LED on silicon (“LEDoS”) structure in which LEDs are disposed as the light-emitting elements LE on the lower substrate BPL (e.g., a backplane substrate formed as a semiconductor circuit board) formed by a semiconductor process using a silicon wafer. However, the disclosure is not limited thereto. In an embodiment, the lower substrate BPL may be a backplane substrate of a different type or structure, for example. Additionally, the embodiments may be applied to display devices of different types and/or structures, or may be applied to devices of different types and/or structures, such as lighting devices.

In an embodiment, the display device 10 may further include an additional component. In an embodiment, the display device 10 may further include at least one of a color filter layer, a protective layer, or an optical structure (e.g., a microlens overlapping the light-emitting elements LE of each pixel PX) disposed on the light-emitting element layer LEL.

The lower substrate BPL may include a base substrate SB, pixel circuits PXC of the pixels PX, the pads PD of FIG. 1. In an embodiment, the lower substrate BPL may further include contact terminals CT and an insulating layer INS disposed on the pixel circuits PXC.

The lower substrate BPL may further include wires electrically connected to the pixels PX and the pads PD. In an embodiment, the lower substrate BPL may include scan lines, data lines, and power lines (e.g., a pixel power line for transmitting a first pixel voltage to the pixels PX, and a common voltage line PL for transmitting a second pixel voltage (e.g., a common voltage) to the pixels PX) electrically connected to the pixels PX, for example. In an embodiment, one of the first pixel voltage and the second pixel voltage may be a high-potential pixel voltage (e.g., an anode voltage), and a remaining (the other) one of the first pixel voltage and the second pixel voltage may be a low-potential pixel voltage (e.g., a cathode voltage). The pixel circuits PXC, the contact terminals CT, the wires, and the pads PD may be disposed or formed on the base substrate SB.

In an embodiment, the lower substrate BPL may be formed through a semiconductor process using a silicon wafer. In an embodiment, the base substrate SB may be a silicon wafer, for example. In an embodiment, the base substrate SB may include or consist of monocrystalline silicon.

The pixel circuits PXC may be disposed on the lower substrate BPL to correspond to the respective pixel areas where the respective pixels PX are disposed. In an embodiment, each of the pixel circuits PXC may include a complementary metal oxide semiconductor (“CMOS”) circuit formed using a semiconductor process. In an embodiment, each of the pixel circuits PXC may include at least one transistor and at least one capacitor formed through a semiconductor process, for example.

In an embodiment, each pixel PX may include the plurality of pixel circuits PXC electrically connected to the light-emitting elements LE of the corresponding pixel PX. In an embodiment, each pixel PX may include a first pixel circuit PXC1 electrically connected to the first light-emitting element LE1, a second pixel circuit PXC2 electrically connected to the second light-emitting element LE2, and a third pixel circuit PXC3 electrically connected to the third light-emitting element LE3, for example. The first pixel circuit PXC1, the second pixel circuit PXC2, and the third pixel circuit PXC3 may control a driving current flowing through the first light-emitting element LE1, the second light-emitting element LE2, and the third light-emitting element LE3 in response to respective driving signals inputted from the outside.

FIGS. 4 and 5 illustrate the schematic shapes and positions of the pixel circuits PXC included in the first pixel PX1 and the second pixel PX2 and the contact terminals CT electrically connected to the pixel circuits PXC, in an embodiment of elements disposed inside the lower substrate BPL. FIGS. 4 and 5 also illustrate the schematic shape and position of the common voltage line PL electrically connected to the light-emitting elements LE of the pixels PX through the common electrode CE, in an embodiment of wires disposed inside the lower substrate BPL. The common voltage line PL may include or consist of a single layer or multiple layers, and may overlap at least a portion of the common electrode CE. In FIGS. 4 and 5, the common voltage line PL is shown as having a shape similar to the contact terminals CT, but the disclosure is not limited thereto. The shape, position (or depth), and cross-sectional structure of the common voltage line PL may be variously changed in other embodiments. The first pixel voltage may be supplied to the light-emitting elements LE through the pixel circuits PXC, the contact terminals CT, and the pixel electrodes ET, and the second pixel voltage may be supplied to the light-emitting elements LE through the common voltage line PL.

Additionally, although FIGS. 4 and 5 illustrate only one insulating layer INS disposed on the pixel circuits PXC and surrounding the contact terminals CT, the disclosure is not limited thereto. In an embodiment, a plurality of insulating layers and a plurality of conductive layers may be disposed on the base substrate SB where the pixel circuits PXC are formed, for example.

The contact terminals CT (or portions of the pixel circuits PXC) and the common voltage line PL may be exposed on the top surface of the lower substrate BPL. The contact terminals CT may contact and/or electrically connected to the respective pixel electrodes ET at the exposed portions. The common voltage line PL may contact and/or electrically connected to the common electrode CE at the exposed portion.

The contact terminals CT may electrically connect the pixel circuits PXC to the respective pixel electrodes ET. In an embodiment, the contact terminal CT electrically connected to the first pixel circuit PXC1 of the first pixel PX1 may be electrically connected to the first pixel electrode ET1 of the first pixel PX1, the contact terminal CT electrically connected to the second pixel circuit PXC2 of the first pixel PX1 may be electrically connected to the second pixel electrode ET2 of the first pixel PX1, and the contact terminal CT electrically connected to the third pixel circuit PXC3 of the first pixel PX1 may be electrically connected to the third pixel electrode ET3 of the first pixel PX1, for example. The contact terminals CT may receive the first pixel voltage from the respective pixel circuits PXC.

In an embodiment, the contact terminals CT may be electrically connected to the respective light-emitting elements LE through the respective pixel electrodes ET and respective electrodes BDE. In an embodiment, the contact terminal CT electrically connected to the first pixel circuit PXC1 of the first pixel PX1 may be electrically connected to the first light-emitting element LE1 of the first pixel PX1 via the first pixel electrode ET1 and the first electrode BDE1 of the first pixel PX1, the contact terminal CT electrically connected to the second pixel circuit PXC2 of the first pixel PX1 may be electrically connected to the second light-emitting element LE2 of the first pixel PX1 via the second pixel electrode ET2 and the second electrode BDE2 of the first pixel PX1, and the contact terminal CT electrically connected to the third pixel circuit PXC3 of the first pixel PX1 may be electrically connected to the third light-emitting element LE3 of the first pixel PX1 via the third pixel electrode ET3 and the third electrode BDE3 of the first pixel PX1, for example.

Although FIGS. 4 and 5 illustrate the contact terminals CT and the pixel circuits PXC in separate configurations, the disclosure is not limited thereto. In an embodiment, the contact terminals CT may be portions of the respective pixel circuits PXC, for example. In an embodiment, the contact terminals CT may be exposed electrodes (or wires) that protrude from the top surfaces of the respective pixel circuits PXC, for example.

The contact terminals CT and the common voltage line PL may include or consist of a conductive material. In an embodiment, the contact terminals CT and the common voltage line PL may include, but not limited to, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or any combinations thereof, for example.

The light-emitting element layer LEL may include the light-emitting elements LE, and electrodes and/or wires electrically connected to the light-emitting elements LE. The light-emitting element layer LEL may further include insulating layers disposed around the light-emitting elements LE.

In an embodiment, the light-emitting elements LE may include a plurality of light-emitting elements LE disposed or stacked sequentially on the lower substrate BPL in each pixel area where each pixel PX is disposed. In an embodiment, the light-emitting elements LE may include the first light-emitting element LE1, the second light-emitting element LE2, and the third light-emitting element LE3 disposed in different layers on the lower substrate BPL in each pixel area and overlapping each other in a plan view, for example. In each pixel area, light of the first color, light of the second color, or light of the third color may be emitted alone, or a combination of at least two of light of the first color, light of the second color, or light of the third color may be emitted.

In an embodiment, the first light-emitting elements LE1 of the pixels PX may be disposed in the same layer and may be simultaneously formed in the same process. The first light-emitting elements LE1 of the pixels PX may be the same type of light-emitting elements (e.g., red micro LEDs) and may include or consist of the same material as each other. The second light-emitting elements LE2 of the pixels PX may be disposed in the same layer and may be simultaneously formed in the same process. The second light-emitting elements LE2 of the pixels PX may be the same type of light-emitting elements (e.g., blue micro LEDs) and may include or consist of the same material as each other. The third light-emitting elements LE3 of the pixels PX may be disposed in the same layer and may be simultaneously formed in the same process. The third light-emitting elements LE3 of the pixels PX may be the same type of light-emitting elements (e.g., green micro LEDs) and may include or consist of the same material as each other.

The first light-emitting elements LE1 may be disposed on the first electrodes BDE1. The second light-emitting elements LE2 may be disposed on the second electrodes BDE2. The third light-emitting elements LE3 may be disposed on the third electrodes BDE3.

Although FIGS. 4 and 5 illustrate an embodiment in which the first light-emitting element LE1, the third light-emitting element LE3, and the second light-emitting element LE2 are sequentially disposed or stacked along the third direction DR3, the disclosure is not limited thereto. In an embodiment, in another embodiment, the positions of the first light-emitting element LE1 and the second light-emitting element LE2 may be reversed, for example. In addition, the stacking order of the light-emitting elements LE disposed in each pixel PX may be variously changed in other embodiments. Further, depending on the arrangement position or stacking order of the light-emitting elements LE, the arrangement position or stacking order of the electrodes BDE and the connection electrodes CNE connected to the respective light-emitting elements LE may also vary.

Each of the light-emitting elements LE may include the first semiconductor layer SEM1, the light-emitting layer EML (also referred to as “active layer”), and the second semiconductor layer SEM2 that are sequentially disposed on the electrode BDE. In an embodiment, each of the light-emitting elements LE may further include at least one of the first contact electrode CTE1 disposed on one surface (e.g., the bottom surface) of the first semiconductor layer SEM1 or the second contact electrode CTE2 disposed on one surface (e.g., the top surface) of the second semiconductor layer SEM2. In the embodiment of FIGS. 4 and 5, the first contact electrode CTE1 and the second contact electrode CTE2 are described as being included in the light-emitting element LE, but the disclosure is not limited thereto. In an embodiment, the first contact electrode CTE1 and the second contact electrode CTE2 may be considered as separate elements from the light-emitting element LE, and may be selectively disposed on at least one surface of the light-emitting element LE, for example.

The first contact electrode CTE1 may be disposed on each electrode BDE. In an embodiment, the first contact electrode CTE1 included in the first light-emitting element LE1 of the first pixel PX1 may be disposed on the first electrode BDE1 of the first pixel PX1, for example. Similarly, the first contact electrode CTE1 included in the second light-emitting element LE2 of each pixel PX may be disposed on the second electrode BDE2 of the corresponding pixel PX, and the first contact electrode CTE1 included in the third light-emitting element LE3 of each pixel PX may be disposed on the third electrode BDE3 of the corresponding pixel PX. The first contact electrode CTE1 may protect the first semiconductor layer SEM1 and may smoothly connect the light-emitting element LE to the electrode BDE.

In an embodiment, the first contact electrode CTE1 may be disposed on an entirety of one surface of the first semiconductor layer SEM1. In an embodiment, the first contact electrode CTE1 may be disposed on an entirety of the bottom surface of the first semiconductor layer SEM1, for example. Accordingly, the first semiconductor layer SEM1 may be stably protected. However, the disclosure is not limited thereto, and the first contact electrode CTE1 may be disposed only on a portion of the first semiconductor layer SEM1.

The first contact electrode CTE1 may include metal, metal oxide, or other conductive materials. In an embodiment, the first contact electrode CTE1 may include or consist of a transparent conductive material (e.g., a transparent conductive oxide such as indium tin oxide (“ITO”) or indium zinc oxide (“IZO”), or other transparent conductive materials), but is not limited thereto.

The first semiconductor layer SEM1 may be disposed on the first contact electrode CTE1. The first semiconductor layer SEM1 may include any one of a p-type semiconductor layer and an n-type semiconductor layer. In describing the embodiment of FIGS. 4 and 5, a case in which the first semiconductor layer SEM1 includes an n-type semiconductor layer and the display device 10 has a common anode structure is described as one of the embodiments, but the disclosure is not limited thereto. In an embodiment, the first semiconductor layer SEM1 may include a p-type semiconductor layer and the display device 10 may be formed in a common cathode structure, for example.

The first semiconductor layer SEM1 may include or consist of a semiconductor material such as GaN, InGaN, InAlGaN, AlGaN, or AlN, and may be an n-type semiconductor layer doped with a first conductivity type dopant (or n-type dopant) such as germanium (Ge), selenium (Se), telium (Te), or tin (Sn). In an embodiment, the first semiconductor layer SEM1 may include or consist of a GaN semiconductor material (e.g., n-GaN) doped with a first conductivity type dopant. However, the material constituting the first semiconductor layer SEM1 is not limited thereto, and the first semiconductor layer SEM1 may consist of various other materials.

The light-emitting layer EML may be disposed between the first semiconductor layer SEM1 and the second semiconductor layer SEM2. The light-emitting layer EML may emit light by recombination of electron-hole pairs generated in response to an electrical signal applied through the first semiconductor layer SEM1 and the second semiconductor layer SEM2.

The light-emitting layer EML may have any one of a single well structure, a multi-well structure, a single quantum well structure, a multi-quantum well (“MQW”) structure, a quantum dot structure, and a quantum wire structure, but the disclosure is not limited thereto. The light-emitting layer EML may include or consist of AlGaN, InGaN, or GaN, and various other materials may constitute the light-emitting layer EML.

The light-emitting layers EML of the light-emitting elements LE disposed in different layers may emit light in different wavelength bands. In an embodiment, the first light-emitting element LE1, the second light-emitting element LE2, and the third light-emitting element LE3 may each include the light-emitting layer EML that emits light in different wavelength bands, for example.

In an embodiment, the light-emitting layer EML of the first light-emitting element LE1 may emit light in a wavelength band corresponding to light of the first color (e.g., light in a red wavelength band), the light-emitting layer EML of the second light-emitting element LE2 may emit light in a wavelength band corresponding to light of the second color (e.g., light in a blue wavelength band), and the light-emitting layer EML of the third light-emitting element may emit light in a wavelength band corresponding to light of the third color (e.g., light in a green wavelength band).

In an embodiment, the light-emitting layer EML may have a multiple quantum well structure including a quantum well layer including InGaN and a barrier layer including GaN, AlGaN, or GaAlN, but is not limited thereto. In an embodiment, when the light-emitting layer EML includes or consists of InGaN, the color or wavelength of light emitted from the light-emitting layer EML may be adjusted by controlling the content of indium (In).

The light-emitting layer EML may emit light in a visible light wavelength band, e.g., light in a wavelength band of approximately 400 nanometers (nm) to approximately 900 nm. In an embodiment, the light-emitting layer EML of the first light-emitting element LE1 may emit red light with a peak wavelength in the range of approximately 610 nm to approximately 650 nm, the light-emitting layer EML of the second light-emitting element LE2 may emit blue light with a peak wavelength in the range of approximately 440 nm to approximately 480 nm, and the light-emitting layer EML of the third light-emitting element LE3 may emit green light with a peak wavelength in the range of approximately 510 nm to approximately 550 nm, for example. The light-emitting layer EML of each of the light-emitting elements LE may emit light of a different color or a different wavelength band other than the above-exemplified colors or wavelength bands.

The second semiconductor layer SEM2 may be disposed on the light-emitting layer EML. The second semiconductor layer SEM2 may include a remaining (the other) one of a p-type semiconductor layer and an n-type semiconductor layer. In describing the embodiment of FIGS. 4 and 5, a case in which the second semiconductor layer SEM2 includes a p-type semiconductor layer is described as one of the embodiments, but the disclosure is not limited thereto. In an embodiment, the first semiconductor layer SEM1 may include a p-type semiconductor layer, and the second semiconductor layer SEM2 may include an n-type semiconductor layer, for example.

The second semiconductor layer SEM2 may include or consist of a semiconductor material such as GaN, InGaN, InAlGaN, AlGaN, or AlN, and may be a p-type semiconductor layer doped with a second conductivity type dopant (or p-type dopant) such as magnesium (Mg), zinc (Zn), calcium (Ca), strontium (Sr), or barium (Ba). In an embodiment, the second semiconductor layer SEM2 may include or consist of a GaN semiconductor material (e.g., p-GaN) doped with a second conductivity type dopant. However, the material constituting the second semiconductor layer SEM2 is not limited thereto, and the second semiconductor layer SEM2 may consist of various other materials.

In an embodiment, the first semiconductor layer SEM1, the light-emitting layer EML, and the second semiconductor layer SEM2 of each of the light-emitting elements LE may be formed from a semiconductor thin film layer (semiconductor epitaxial stack) or epi-layers formed by epitaxial growth on a semiconductor substrate.

The second contact electrode CTE2 may be disposed on the second semiconductor layer SEM2. The second contact electrode CTE2 may protect the second semiconductor layer SEM2 and may smoothly connect the light-emitting element LE to the common electrode CE.

In an embodiment, the second contact electrode CTE2 may be disposed an entirety of on one surface of the second semiconductor layer SEM2, for example. In an embodiment, the second contact electrode CTE2 may be disposed on an entirety of the top surface of the second semiconductor layer SEM2, for example. Accordingly, the second semiconductor layer SEM2 may be stably protected. However, the disclosure is not limited thereto, and the second contact electrode CTE2 may be disposed only on a portion of the second semiconductor layer SEM2.

The second contact electrode CTE2 may include metal, metal oxide, or other conductive materials. In an embodiment, the second contact electrode CTE2 may include or consist of a transparent conductive material (e.g., a transparent conductive oxide such as indium tin oxide (“ITO”) or indium zinc oxide (“IZO”), or other transparent conductive materials), but is not limited thereto. Accordingly, light generated in the light-emitting element LE may pass through the second contact electrode CTE2 and be emitted to the upper side of the light-emitting element LE.

In an embodiment, the light-emitting elements LE may have differentiated and/or optimized shapes or structures according to their respective characteristics. In an embodiment, at least two of the light-emitting elements LE among the first light-emitting element LE1, the second light-emitting element LE2 and the third light-emitting element LE3 may include respective sidewalls (or side surfaces) that have different angles with respect to their respective bottom surfaces (e.g., the bottom surfaces of the first contact electrodes CTE1 or the first semiconductor layers SEM1), the lower substrate BPL, and/or their respective electrodes BDE, for example. In an embodiment, an angle (also referred to as a first angle) θ1 defined between the bottom surface (also referred to as a first bottom surface) and the sidewall (also referred to as a first sidewall) of the first light-emitting element LE1 may differ from an angle (also referred to as a second angle) θ2 defined between the bottom surface (also referred to as a second bottom surface) and the sidewall (also referred to as a second sidewall) of the second light-emitting element LE2, for example. An angle (also referred to as a third angle) 3 defined between the bottom surface (also referred to as a third bottom surface) and the sidewall (also referred to as a third sidewall) of the third light-emitting element LE3 may be substantially the same as the angle θ1 defined between the bottom surface and the sidewall of the first light-emitting element LE1 or the angle θ2 defined between the bottom surface and the sidewall of the second light-emitting element LE2, or it may differ from both the angle θ1 defined between the bottom surface and the sidewall of the first light-emitting element LE1 and the angle θ2 defined between the bottom surface and the sidewall of the second light-emitting element LE2.

In an embodiment, at least one light-emitting element LE among the first light-emitting element LE1, the second light-emitting element LE2, and the third light-emitting element LE3 may include an inclined sidewall with a taper angle. Further, at least one light-emitting element LE among the first light-emitting element LE1, the second light-emitting element LE2, and the third light-emitting element LE3 may include a vertical sidewall. Accordingly, at least two light-emitting elements LE among the first light-emitting element LE1, the second light-emitting element LE2, and the third light-emitting element LE3 may have different shapes (e.g., different cross-sectional shapes).

In an embodiment, the light-emitting element LE that is relatively insensitive to surface defects among the first light-emitting element LE1, the second light-emitting element LE2, and the third light-emitting element LE3 may include an inclined sidewall. Additionally, the light-emitting element LE that is relatively sensitive to surface defects among the first light-emitting element LE1, the second light-emitting element LE2, and the third light-emitting element LE3 may include a vertical sidewall.

In an embodiment, the first light-emitting element LE1, the second light-emitting element LE2, and the third light-emitting element LE3 may emit light in different wavelength bands, and the content of indium (In) contained in the light-emitting layers EML (e.g., the content of indium (In) in the quantum well layers including or consisting of InGaN) of the first light-emitting element LE1, the second light-emitting element LE2, and the third light-emitting element LE3 may differ from each other. In an embodiment, the light-emitting layer EML of the light-emitting element LE that emits light of a longer wavelength may include or consist of indium (In) at a higher content than the light-emitting layer EML of the light-emitting element LE that emits light of a shorter wavelength, for example. In an embodiment, the light-emitting layer (also referred to as a first light-emitting layer) EML of the first light-emitting element LE1 that emits red light may include or consist of indium (In) at a higher content than the light-emitting layer (also referred to as a second light-emitting layer) EML of the second light-emitting element LE2 that emits blue light and the light-emitting layer ((also referred to as a third light-emitting layer)) EML of the third light-emitting element LE3 that emits green light, for example. The light-emitting layer EML of the second light-emitting element LE2, which emits light of the shortest wavelength among the first light-emitting element LE1, the second light-emitting element LE2, and the third light-emitting element LE3, may include or consist of indium (In) at a lower content than the light-emitting layer EML of the first light-emitting element LE1 and the light-emitting layer EML of the third light-emitting element LE3.

In an embodiment, among the first light-emitting element LE1, the second light-emitting element LE2, and the third light-emitting element LE3, the light-emitting element LE that emits light in the longest wavelength band and/or has the highest indium (In) content in the light-emitting layer EML may include an inclined sidewall (e.g., a side surface formed as an inclined surface). In describing embodiments, the term “inclined sidewall” may refer to a sidewall that is inclined with a taper angle with respect to the bottom surface (or the top surface) of each light-emitting element LE. In an embodiment, when it is stated that the light-emitting element LE includes an inclined sidewall, it may mean that the sidewall of the light-emitting element LE is inclined at an angle of approximately ±5° or more with respect to a direction (e.g., the third direction DR3) perpendicular to the bottom surface (or the top surface) of the light-emitting element LE, for example. In an embodiment, in the light-emitting element LE including an inclined sidewall, the taper angle defined between the bottom surface and the sidewall thereof may be in the range of less than 85° or greater than 95°. Additionally, in describing embodiments, the shape of the sidewall of the light-emitting element LE may be based primarily on the shape of the sidewalls of the first semiconductor layer SEM1, the light-emitting layer EML, and the second semiconductor layer SEM2.

In an embodiment, among the first light-emitting element LE1, the second light-emitting element LE2, and the third light-emitting element LE3, the first light-emitting element LE1, which emits light (e.g., red light) of a longer wavelength and has the highest indium (In) content in the light-emitting layer EML, may include an inclined sidewall, for example. In an embodiment, the first light-emitting element LE1 (or the semiconductor layers of the first light-emitting element LE1 including the first semiconductor layer SEM1, the light-emitting layer EML, and the second semiconductor layer SEM2) may have a substantially trapezoidal cross-sectional shape. When the first light-emitting element LE1 includes an inclined sidewall, the angle θ1 defined between the sidewall of the first semiconductor layer SEM1, the light-emitting layer EML, and the second semiconductor layer SEM2 of the first light-emitting element LE1 and the bottom surface (or the first electrode BDE1 and/or the lower substrate BPL) of the first light-emitting element LE1 may be in the range of less than 85° or greater than 95°. Each of the first contact electrode CTE1 and the second contact electrode CTE2 of the first light-emitting element LE1 may include an inclined sidewall, similarly to the first semiconductor layer SEM1, the light-emitting layer EML, and the second semiconductor layer SEM2, or may include a vertical sidewall that is substantially perpendicular to the bottom surface of the first light-emitting element LE1. In an embodiment, each of the first contact electrode CTE1 and the second contact electrode CTE2 of the first light-emitting element LE1 may or may not have a taper angle, and its shape is not particularly limited, for example.

In an embodiment, among the first light-emitting element LE1, the second light-emitting element LE2, and the third light-emitting element LE3, the light-emitting element LE that emits light in the shortest wavelength band or has the lowest indium (In) content in the light-emitting layer EML may include a vertical sidewall. In describing embodiments, the term “vertical sidewall” may refer to a sidewall that has an angle within a predetermined range, e.g., within approximately +5°, with respect to a direction (e.g., the third direction DR3) perpendicular to the bottom surface (or the top surface) of each light-emitting element LE and is substantially perpendicular to the bottom surface or the top surface of the corresponding light-emitting element LE. In an embodiment, when it is stated that the light-emitting element LE includes a vertical sidewall, it may mean that the sidewall of the light-emitting element LE is substantially perpendicular to the bottom surface (or the top surface) of the light-emitting element LE, for example. In an embodiment, in the light-emitting element LE including a vertical sidewall, the angle defined between the bottom surface and the sidewall may be in the range of approximately 85° to 95°.

In an embodiment, among the first light-emitting element LE1, the second light-emitting element LE2, and the third light-emitting element LE3, the second light-emitting element LE2, which emits light (e.g., blue light) of a shorter wavelength and has the lowest indium (In) content in the light-emitting layer EML, may include a vertical sidewall, for example. In an embodiment, the second light-emitting element LE2 may have a substantially quadrangular, e.g., rectangular or square cross-sectional shape, and the angle θ2 defined between the sidewall of the first semiconductor layer SEM1, the light-emitting layer EML, and the second semiconductor layer SEM2 of the second light-emitting element LE2 and the bottom surface (or the second electrode BDE2 and/or the lower substrate BPL) of the second light-emitting element LE2 may be in the range of 85° to 95°. In an embodiment, the angle defined between the sidewall and the bottom surface of the second light-emitting element LE2 may be approximately 90°. Each of the first contact electrode CTE1 and the second contact electrode CTE2 of the second light-emitting element LE2 may include a vertical sidewall, similarly to the first semiconductor layer SEM1, the light-emitting layer EML, and the second semiconductor layer SEM2, or may include an inclined sidewall having a taper angle with respect to the bottom surface of the second light-emitting element LE2. In another embodiment, the shape of each of the first contact electrode CTE1 and the second contact electrode CTE2 of the second light-emitting element LE2 is not particularly limited.

Compared to the first light-emitting element LE1 and the second light-emitting element LE2, the third light-emitting element LE3, which emits light (e.g., green light) of an intermediate wavelength, may include an inclined sidewall or a vertical sidewall. In an embodiment, the third light-emitting element LE3 may have a substantially quadrangular cross-sectional shape, e.g., rectangular or square cross-sectional shape, and the angle θ3 defined between the sidewall of the first semiconductor layer SEM1, the light-emitting layer EML, and the second semiconductor layer SEM2 of the third light-emitting element LE3 and the bottom surface (or the third electrode BDE3 and/or the lower substrate BPL) of the third light-emitting element LE3 may be in the range of 85° to 95°. Each of the first contact electrode CTE1 and the second contact electrode CTE2 of the third light-emitting element LE3 may include a vertical sidewall or an inclined sidewall.

In an embodiment, the light-emitting element LE including a vertical sidewall may first be formed to include an inclined sidewall by primarily etching semiconductor layers (e.g., a semiconductor thin film layer or epi-layers) formed (e.g., epitaxially grown) on a semiconductor substrate while the semiconductor layers are disposed on the semiconductor substrate or on the lower substrate BPL, and then may be formed to include the vertical sidewall through an additional process such as wet treatment. Through the wet treatment process or the like, the surface (e.g., the side surface exposed to plasma during the etching process) of the light-emitting element LE may be refined and surface defects may be reduced. Accordingly, in the case of the light-emitting element LE including a vertical sidewall, non-emission recombination of electrons and holes due to surface defects may be reduced, and the efficiency (e.g., luminous efficiency) of the light-emitting element LE may be increased.

In an embodiment, the light-emitting element LE including an inclined sidewall may be manufactured or formed to include the inclined sidewall by etching semiconductor layers for forming the first semiconductor layer SEM1, the light-emitting layer EML, and the second semiconductor layer SEM2, and may be manufactured or formed without undergoing an additional process such as the aforementioned wet treatment. Accordingly, in the case of the light-emitting element LE including an inclined sidewall, volume loss of the light-emitting layer EML or the like that may occur during an additional process may be reduced or prevented, and the light-emitting element LE may be formed in a relatively large size. In an embodiment, the light-emitting element LE including an inclined sidewall may be formed in a larger size than the light-emitting element LE including a vertical sidewall in a plan view, for example. As the area of the light-emitting layer EML is increased or secured, the light efficiency of the light-emitting element LE may be increased. In an embodiment, in a plan view, the size of the first light-emitting element LE1 may be larger than that of the size of the second light-emitting element LE2 and/or the size of the third light-emitting element LE3. However, the disclosure is not limited thereto, and the planar shape or relative size of each of the light-emitting elements LE may be variously changed.

In an embodiment, the light-emitting element LE including an inclined sidewall may be a light-emitting element LE in which the indium (In) content in the light-emitting layer EML is relatively high. When the indium (In) content in the light-emitting layer EML is high, the rate at which carriers move to the surface may decrease due to indium localization occurring inside the light-emitting layer EML. As a result, influence due to surface defects of the light-emitting element LE may be reduced. In an embodiment, in the case of the light-emitting element LE including the light-emitting layer EML with a relatively high indium (In) content, the reduction in the efficiency of the light-emitting element LE due to surface defects may be insignificant even without undergoing an additional process such as wet treatment, for example. Additionally, by omitting or minimizing an additional process, it is possible to prevent or reduce volume loss of the light-emitting layer EML or the like, thereby increasing the efficiency (e.g., luminous efficiency) of the light-emitting element LE.

As described above, in embodiments, at least two types of light-emitting elements LE (e.g., the first light-emitting element LE1 and the second light-emitting element LE2) that emit light of different colors depending on the wavelength band of light emitted from each light-emitting element LE and/or the indium (In) content of the light-emitting layer EML may be formed in different structures and/or shapes. In an embodiment, depending on the types of the light-emitting elements LE, a process such as wet treatment may be selectively performed to form the light-emitting elements LE in different shapes, for example. In an alternative embodiment, by adjusting the extent (e.g., process time or intensity) to which the wet treatment process is performed, the surface characteristics or shapes of the light-emitting elements LE may be adjusted. Accordingly, the luminous efficiency of the light-emitting elements LE may be improved or optimized according to the characteristics of each light-emitting element LE, and the light efficiency of the light-emitting elements LE and the pixel PX including them may be increased.

In an embodiment, the first light-emitting element LE1, which may be relatively insensitive to surface defects, may be manufactured or formed to include an inclined sidewall without undergoing an additional process such as wet treatment, thereby preventing or minimizing the reduction in the size of the light-emitting layer EML of the first light-emitting element LE1. The second light-emitting element LE2, which may be relatively sensitive to surface defects, may undergo an additional process such as wet treatment to refine the damaged surface and be manufactured or formed to include a vertical sidewall, thereby reducing or minimizing surface defects of the second light-emitting element LE2.

Additionally, the first light-emitting elements LE1, the second light-emitting elements LE2, and the third light-emitting elements LE3 may be disposed in different layers within the light-emitting element layer LEL, and may be individually etched or formed. In an embodiment, the first light-emitting elements LE1, the second light-emitting elements LE2, and the third light-emitting elements LE3 may be manufactured or formed to include inclined sidewalls or vertical sidewalls by disposing or bonding respective semiconductor layers (e.g., epi-layers sequentially formed to form the first semiconductor layer SEM1, the light-emitting layer EML, and the second semiconductor layer SEM2 of each of the first light-emitting elements LE1, the second light-emitting elements LE2, and the third light-emitting elements LE3), formed by epitaxial growth on respective semiconductor substrates, onto the lower substrate BPL and then etching the semiconductor layers. In another embodiment, at least one of the first light-emitting elements LE1, the second light-emitting elements LE2, or the third light-emitting elements LE3 may be etched on their respective semiconductor substrates to include an inclined sidewall or a vertical sidewall and then disposed or bonded onto the lower substrate BPL.

In an embodiment, the cross-sectional shape of the light-emitting elements LE or the stacking order of the first semiconductor layer SEM1, the light-emitting layer EML, and the second semiconductor layer SEM2 may vary depending on the arrangement order of the semiconductor layers for forming the light-emitting elements LE or the sequence of the etching process and the bonding process. In an embodiment, when the semiconductor layers are etched in a state in which the semiconductor layer (e.g., an n-type semiconductor layer) for forming the first semiconductor layer SEM1 is disposed below the semiconductor layer (e.g., a p-type semiconductor layer) for forming the second semiconductor layer SEM2, for example, the first semiconductor layer SEM1 may have a larger area than the second semiconductor layer SEM2. Conversely, when the semiconductor layers are etched in a state in which the semiconductor layer for forming the second semiconductor layer SEM2 is disposed below the semiconductor layer for forming the first semiconductor layer SEM1, the second semiconductor layer SEM2 may have a larger area than the first semiconductor layer SEM1. In an embodiment, the first light-emitting element LE1, which is formed to include an inclined sidewall without undergoing a wet treatment process or by shortening the time of the wet treatment process, may have a tapered or reverse-tapered cross-sectional shape, for example. By controlling the arrangement direction or cross-sectional shape of the light-emitting element LE including an inclined sidewall, the light emission characteristics such as a light collection direction may be appropriately controlled or changed.

In an embodiment, the electrodes of the light-emitting element layer LEL may include the pixel electrodes ET and the connection electrodes CNE electrically connected to opposite ends of the light-emitting elements LE, the electrodes BDE electrically connected between the light-emitting elements LE and the pixel electrodes ET, and the common electrode CE electrically connected to one ends of the light-emitting elements LE through the connection electrodes CNE. Although FIGS. 4 and 5 illustrate an embodiment in which the common electrode CE is connected to the light-emitting elements LE through the connection electrodes CNE, the disclosure is not limited thereto. In an embodiment, the common electrode CE may be directly in contact with or connected to the light-emitting elements LE, or the common electrode CE and the connection electrodes CNE may be integrated into one electrode, for example. Additionally, although FIGS. 4 and 5 illustrate the display device 10 with a structure in which the electrodes BDE are disposed above the lower insulating layer BIL covering the lower substrate BPL, and the light-emitting elements LE are bonded to the lower substrate BPL by the electrodes BDE, the structure of the display device 10 in embodiments is not limited thereto. In an embodiment, the light-emitting elements LE may be appropriately disposed on the lower substrate BPL using other connection electrodes or wires instead of a bonding method, for example.

In an embodiment, the insulating layers of the light-emitting element layer LEL may include a lower insulating layer BIL, a first insulating layer IL1, a first inter-insulating layer INL1, a second insulating layer IL2, a second inter-insulating layer INL2, a third insulating layer IL3, and an upper insulating layer UIL that are sequentially disposed on the lower substrate BPL. Each of the insulating layers of the light-emitting element layer LEL may be constituted with a single layer or multiple layers including at least one insulating material. In an embodiment, each of the insulating layers of the light-emitting element layer LEL may include an inorganic insulating layer including or consisting of an inorganic insulating material (e.g., silicon oxide (SiOₓ), silicon nitride (SiNₓ), silicon oxynitride (SiOₓN_{y}), silicon oxycarbide (SiOₓC_{y}), aluminum oxide (AlₓO_{y}), aluminum nitride (AlNₓ), zirconium oxide (ZrOₓ), hafnium oxide (HfOₓ), titanium oxide (TiOₓ), or other inorganic insulating materials), but is not limited thereto.

The pixel electrodes ET and the common electrode CE may be disposed on the lower substrate BPL. The pixel electrodes ET and the common electrode CE may include a conductive material. In an embodiment, the pixel electrodes ET and the common electrode CE may include at least one of gold (Au), copper (Cu), tin (Sn), titanium (Ti), aluminum (Al), silver (Ag), or other metals, for example.

The pixel electrodes ET may be disposed between the lower substrate BPL and the electrodes BDE to connect the lower substrate BPL to the electrodes BDE. In an embodiment, the pixel electrodes ET may be electrically connected between the contact terminals CT of the respective pixel circuits PXC and the electrodes BDE corresponding to the respective pixel circuits PXC, for example.

The pixel electrodes ET may penetrate at least one of the insulating layers of the light-emitting element layer LEL to be electrically connected to the contact terminals CT of the lower substrate BPL. In an embodiment, the first pixel electrode ET1 of the first pixel PX1 may penetrate the lower insulating layer BIL to be electrically connected to the contact terminal CT that is connected to the first pixel circuit PXC1 of the first pixel PX1, for example. Further, the first pixel electrode ET1 of the first pixel PX1 may be electrically connected to the first electrode BDE1 of the first pixel PX1 disposed on the lower insulating layer BIL, and may be electrically connected, through the first electrode BDE1, to the first light-emitting element LE1 disposed in the first pixel PX1. The second pixel electrode ET2 of the first pixel PX1 may penetrate the lower insulating layer BIL, the first insulating layer IL1, the first inter-insulating layer INL1, the second insulating layer IL2, and the second inter-insulating layer INL2 to be electrically connected to the contact terminal CT that is connected to the second pixel circuit PXC2 of the first pixel PX1. Further, the second pixel electrode ET2 of the first pixel PX1 may be electrically connected to the second electrode BDE2 of the first pixel PX1 disposed on the second inter-insulating layer INL2, and may be electrically connected to the second light-emitting element LE2 of the first pixel PX1 through the second electrode BDE2. The third pixel electrode ET3 of the first pixel PX1 may penetrate the lower insulating layer BIL, the first insulating layer IL1, and the first inter-insulating layer INL1 to be electrically connected to the contact terminal CT that is connected to the third pixel circuit PXC3 of the first pixel PX1. Further, the third pixel electrode ET3 of the first pixel PX1 may be electrically connected to the third electrode BDE3 of the first pixel PX1 disposed on the first inter-insulating layer INL1, and may be electrically connected to the third light-emitting element LE3 of the first pixel PX1 through the third electrode BDE3. In the same manner, the pixel electrodes ET of the second pixel PX2 and other pixels PX may be electrically connected between the contact terminals CT of the respective pixel circuits PXC and the respective light-emitting elements LE.

The common electrode CE may penetrate at least one of the insulating layers of the light-emitting element layer LEL to be electrically connected between the common voltage line PL of the lower substrate BPL and the connection electrodes CNE. In an embodiment, the common electrode CE may penetrate the lower insulating layer BIL, the first insulating layer IL1, the first inter-insulating layer INL1, the second insulating layer IL2, the second inter-insulating layer INL2, and the third insulating layer IL3, for example.

The electrodes BDE may be disposed below the light-emitting elements LE. The electrodes BDE may be electrically connected to the first contact electrodes CTE1 (or the first semiconductor layers SEM1) of the respective light-emitting elements LE. In an embodiment, the electrodes BDE may include the first electrodes BDE1, the third electrodes BDE3, and the second electrodes BDE2, which are sequentially disposed or stacked on the lower substrate BPL along the third direction DR3. In an embodiment, the first electrodes BDE1 of the pixels PX may be disposed separately from each other on the lower insulating layer BIL, the second electrodes BDE2 of the pixels PX may be disposed separately from each other on the second inter-insulating layer INL2, and the third electrodes BDE3 of the pixels PX may be disposed separately from each other on the first inter-insulating layer INL1, for example. The arrangement order or stacking order of the first electrodes BDE1, the third electrodes BDE3, and the second electrodes BDE2 may vary depending on embodiments.

The electrodes BDE may include or consist of a conductive material for stably disposing the light-emitting elements LE on the lower substrate BPL. In an embodiment, when the light-emitting elements LE are disposed on the lower substrate BPL through a bonding process, the electrodes BDE may include or consist of a conductive material, e.g., a eutectic metal, suitable for the bonding process or a transparent conductive material capable of the bonding process. However, the disclosure is not limited thereto, and the light-emitting elements LE may be disposed on the lower substrate BPL through other types of processes. In this case, the type of conductive material used to form the electrodes BDE is not particularly limited. In the following, an embodiment related to the electrodes BDE will be described, in which the electrodes BDE include or consist of a conductive material capable of a bonding process.

In an embodiment, the electrodes BDE disposed at the lowermost part among the electrodes BDE may include a bonding metal layer including or consisting of at least one metal suitable for a bonding process and a capping layer disposed on at least one surface of the bonding metal layer. In an embodiment, each of the first electrodes BDE1 may include or consist of multiple layers in which a first capping layer including or consisting of titanium (Ti) or another barrier material (e.g., an anti-diffusion material), a bonding metal layer including or consisting of a gold (Au)-tin (Sn) alloy or another bonding metal, and a second capping layer including or consisting of titanium (Ti) or another barrier material are sequentially stacked, for example, but is not limited thereto. In an embodiment, each of the first electrodes BDE1 may further include a reflective layer including or consisting of a metal, such as aluminum (Al), with relatively high reflectivity, but is not limited thereto.

In an embodiment, the electrodes BDE disposed on at least one light-emitting element LE may include or consist of a transparent conductive material capable of a bonding process. In an embodiment, the second electrodes BDE2 and the third electrodes BDE3 may include or consist of a transparent conductive oxide, such as indium tin oxide (“ITO”) or zinc oxide (ZnO), or another transparent conductive material, for example. Accordingly, light emitted from the first light-emitting elements LE1 may pass through the second electrodes BDE2 and the third electrodes BDE3.

The connection electrodes CNE may be disposed on top of the light-emitting elements LE. Although FIGS. 4 and 5 illustrate an embodiment in which the connection electrodes CNE are disposed entirely on the respective light-emitting elements LE, the disclosure is not limited thereto. In an embodiment, the connection electrodes CNE may be disposed locally on only portions of the respective light-emitting elements LE, for example.

The connection electrodes CNE may include first connection electrodes CNE1, second connection electrodes CNE2, and third connection electrodes CNE3. The first connection electrodes CNE1 may be disposed on the first light-emitting elements LE1 and the first insulating layer IL1. The first connection electrodes CNE1 may electrically connect the first light-emitting elements LE1 to the common electrode CE. The second connection electrodes CNE2 may be disposed on the second light-emitting elements LE2 and the third insulating layer IL3. The second connection electrodes CNE2 may electrically connect the second light-emitting elements LE2 to the common electrode CE. The third connection electrodes CNE3 may be disposed on the third light-emitting elements LE3 and the second insulating layer IL2. The third connection electrodes CNE3 may electrically connect the third light-emitting elements LE3 to the common electrode CE.

The connection electrodes CNE may include or consist of metal, metal oxide, or other conductive materials. In an embodiment, the connection electrodes CNE may include or consist of a transparent conductive material (e.g., a transparent conductive oxide such as indium tin oxide (“ITO”) or indium zinc oxide (“IZO”), or other transparent conductive materials), but are not limited thereto.

The lower insulating layer BIL may be disposed on the lower substrate BPL. The lower insulating layer BIL may define openings (e.g., contact holes or via holes) that expose the contact terminals CT and the common voltage line PL of the lower substrate BPL. At least portions of the pixel electrodes ET and the common electrode CE may be disposed in the openings. In an embodiment, the lower insulating layer BIL may surround at least portions of the pixel electrodes ET and the common electrode CE, for example.

The first insulating layer IL1 may be disposed on the lower insulating layer BIL. The first insulating layer IL1 may surround the first electrodes BDE1 and the first light-emitting elements LE1. The first insulating layer IL1 may surround at least portions of the pixel electrodes ET (e.g., the second pixel electrodes ET2 and the third pixel electrodes ET3) and the common electrode CE.

The first inter-insulating layer INL1 may be disposed on the first insulating layer IL1. The first inter-insulating layer INL1 may cover the first connection electrodes CNE1. The first inter-insulating layer INL1 may surround at least portions of the pixel electrodes ET and the common electrode CE.

The second insulating layer IL2 may be disposed on the first inter-insulating layer INL1. The second insulating layer IL2 may surround the third electrodes BDE3 and the third light-emitting elements LE3. The second insulating layer IL2 may surround at least portions of the pixel electrodes ET (e.g., the second pixel electrodes ET2) and the common electrode CE.

The second inter-insulating layer INL2 may be disposed on the second insulating layer IL2. The second inter-insulating layer INL2 may cover the third connection electrodes CNE3. The second inter-insulating layer INL2 may surround at least portions of the pixel electrodes ET and the common electrode CE.

The third insulating layer IL3 may be disposed on the second inter-insulating layer INL2. The third insulating layer IL3 may surround the second electrodes BDE2 and the second light-emitting elements LE2. The third insulating layer IL3 may surround at least a portion of the common electrode CE.

The upper insulating layer UIL may be disposed on the third insulating layer IL3. The upper insulating layer UIL may be an insulating layer disposed at the uppermost part of the light-emitting element layer LEL and may cover the light-emitting elements LE, electrodes, and/or wires disposed in the light-emitting element layer LEL. In an embodiment, the upper insulating layer UIL may cover the second connection electrodes CNE2 and the common electrode CE, for example.

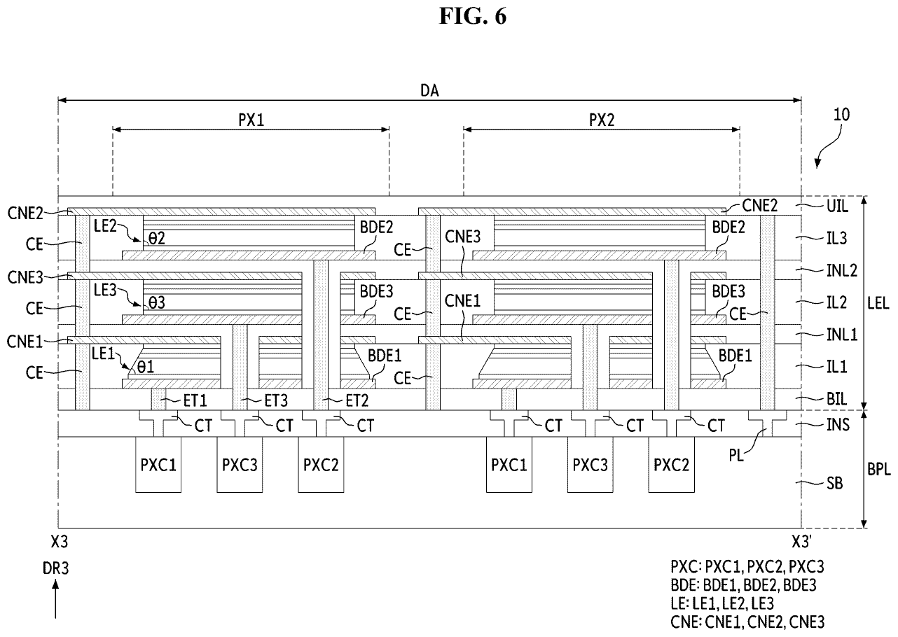

FIG. 6 is a cross-sectional view showing an embodiment of a display device. In an embodiment, FIG. 6 illustrates an embodiment of a cross-section of a portion of the display area DA corresponding to line X3-X3′ of FIG. 3, for example.

In describing the following embodiments, redundant descriptions of components substantially identical or similar to those of at least an embodiment described above are omitted. In an embodiment, in describing the embodiment of FIGS. 3 and 6, detailed descriptions of configurations that are substantially the same or similar to those of the embodiment of FIGS. 2, 4, and 5 are omitted, for example.

Referring to FIGS. 3 and 6, in each pixel PX, the second pixel electrode ET2 may penetrate the first light-emitting element LE1 and the third light-emitting element LE3 to be connected to the second electrode BDE2. In an embodiment, the first light-emitting element LE1 and the third light-emitting element LE3 may each define an opening that is larger than the area of the second pixel electrode ET2 at the position where the second pixel electrode ET2 is disposed, for example. Similarly, the first electrode BDE1, the first connection electrode CNE1, the third electrode BDE3, and the third connection electrode CNE3 may be opened to a larger area than the second pixel electrode ET2 at the position where the second pixel electrode ET2 is disposed. The second pixel electrode ET2 may be disposed within the opening and may be surrounded by an insulating layer (e.g., a portion of the second inter-insulating layer INL2). Accordingly, electrical stability (e.g., insulation) may be ensured between the first light-emitting element LE1 and the third light-emitting element LE3, and the second pixel electrode ET2.

In the same way, in each pixel PX, the third pixel electrode ET3 may penetrate the first light-emitting element LE1 to be connected to the third electrode BDE3. In an embodiment, the first light-emitting element LE1 may define an opening that is larger than the area of the third pixel electrode ET3 at the position where the third pixel electrode ET3 is disposed, for example. Similarly, the first electrode BDE1 and the first connection electrode CNE1 may be opened to a larger area than the third pixel electrode ET3 at the position where the third pixel electrode ET3 is disposed. The third pixel electrode ET3 may be disposed within the opening and may be surrounded by an insulating layer (e.g., a portion of the first inter-insulating layer INL1). Accordingly, electrical stability (e.g., insulation) may be ensured between the first light-emitting element LE1 and the third pixel electrode ET3.

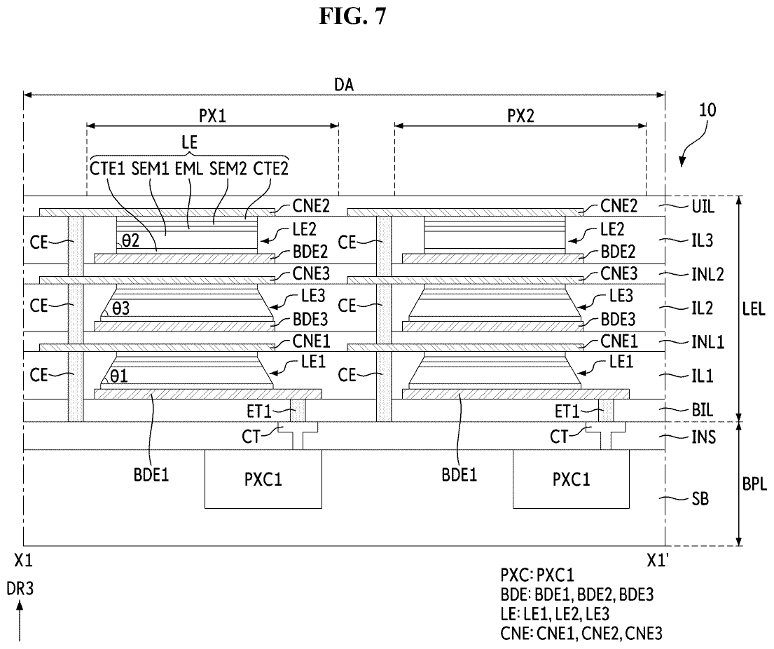

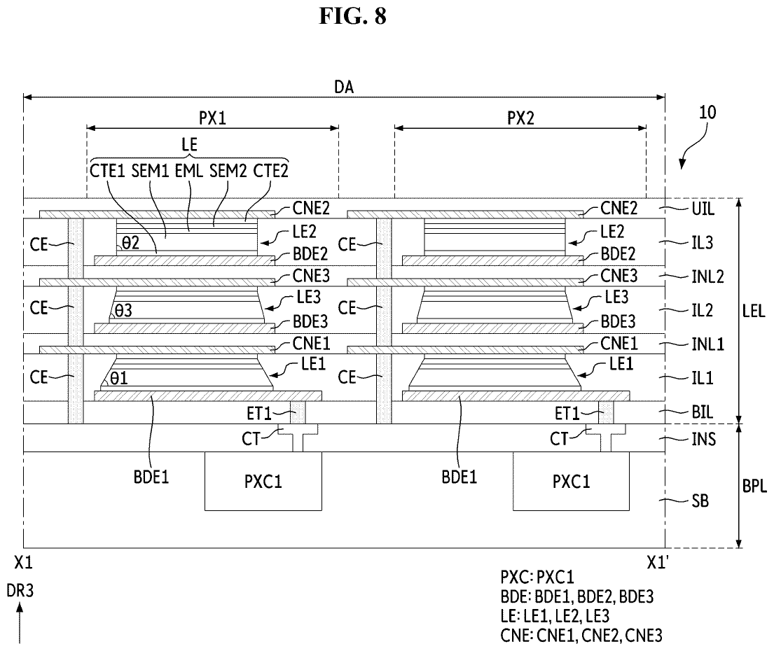

FIG. 7 is a cross-sectional view showing an embodiment of a display device. FIG. 8 is a cross-sectional view showing a display device. In an embodiment, FIGS. 7 and 8 illustrate embodiments of a cross-section of a portion of the display area DA corresponding to line X1-X1′ of FIG. 2, for example. FIGS. 7 and 8 show embodiments that differ from the embodiment of FIGS. 4 and 5 with respect to the third light-emitting element LE3.

Referring to FIGS. 7 and 8, the third light-emitting element LE3 may include an inclined sidewall. In an embodiment, the third light-emitting element LE3 may have a substantially trapezoidal cross-sectional shape, for example. When the third light-emitting element LE3 includes an inclined sidewall, the angle θ3 defined between the sidewall of the first semiconductor layer SEM1, the light-emitting layer EML, and the second semiconductor layer SEM2 of the third light-emitting element LE3 and the bottom surface (or the third electrode BDE3 and/or the lower substrate BPL) of the third light-emitting element LE3 may be in the range of less than 85° or greater than 95°. Each of the first contact electrode CTE1 and the second contact electrode CTE2 of the third light-emitting element LE3 may include an inclined sidewall, similarly to the first semiconductor layer SEM1, the light-emitting layer EML, and the second semiconductor layer SEM2, or may include a vertical sidewall that is substantially perpendicular to the bottom surface of the third light-emitting element LE3.

In an embodiment, as shown in FIG. 7, the sidewall of the first light-emitting element LE1 and the sidewall of the third light-emitting element LE3 may have substantially the same inclination. In an embodiment, the sidewall of the first light-emitting element LE1 and the sidewall of the third light-emitting element LE3 may be inclined surfaces corresponding to an angle of 60°, for example.

In another embodiment, as shown in FIG. 8, the sidewall of the first light-emitting element LE1 and the sidewall of the third light-emitting element LE3 may have different inclinations. In an embodiment, the angle θ3 defined between the sidewall of the third light-emitting element LE3 and the bottom surface of the third light-emitting element LE3 may have a value between the angle θ1 defined between the sidewall of the first light-emitting element LE1 and the bottom surface of the first light-emitting element LE1 and the angle θ2 defined between the sidewall of the second light-emitting element LE2 and the bottom surface of the second light-emitting element LE2, for example. In an embodiment, the sidewall of the first light-emitting element LE1 and the sidewall of the third light-emitting element LE3 may be inclined surfaces corresponding to angles of 60° and 75°, respectively, and the sidewall of the second light-emitting element LE2 may form a right angle with the bottom surface. Furthermore, the inclinations of the sidewall of the first light-emitting element LE1 and the sidewall of the third light-emitting element LE3 may be variously changed in other embodiments.

In an embodiment, the third light-emitting element LE3 may be manufactured to include a sidewall with a greater inclination than the sidewall of the first light-emitting element LE1 through a process such as wet treatment. Additionally, the third light-emitting element LE3 may be manufactured to include a sidewall with a smaller inclination than the sidewall of the second light-emitting element LE2 through a wet treatment process or the like performed for a shorter period of time than the wet treatment process for the second light-emitting element LE2. Accordingly, the third light-emitting element LE3 may have reduced or mitigated surface defects compared to the first light-emitting element LE1, and may have a larger area than the second light-emitting element LE2. However, the method for differentiating the shapes or sidewall inclinations of the first light-emitting element LE1, the second light-emitting element LE2, and the third light-emitting element LE3 is not limited thereto. Further, the relative sizes (e.g., areas) of the first light-emitting element LE1, the second light-emitting element LE2, and the third light-emitting element LE3 are not solely determined by the shapes of the sidewalls and may vary in other embodiments.

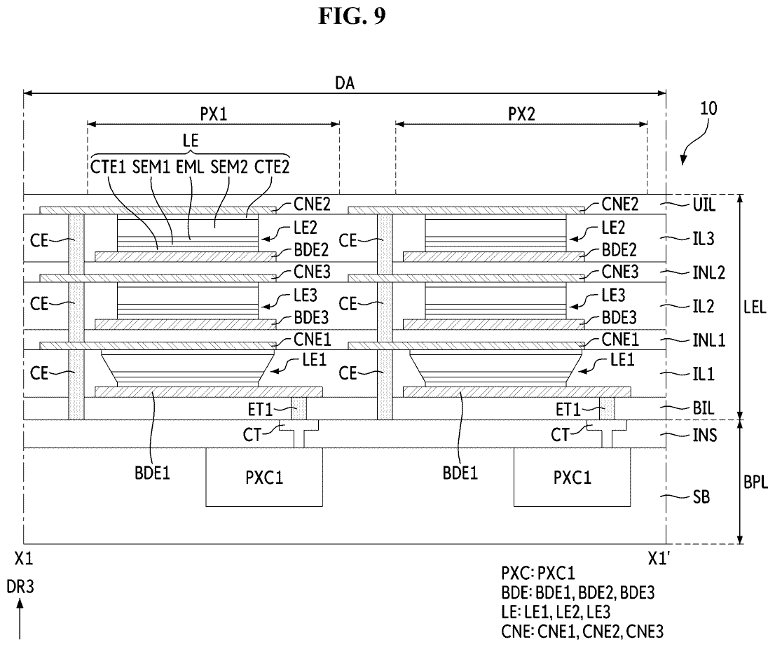

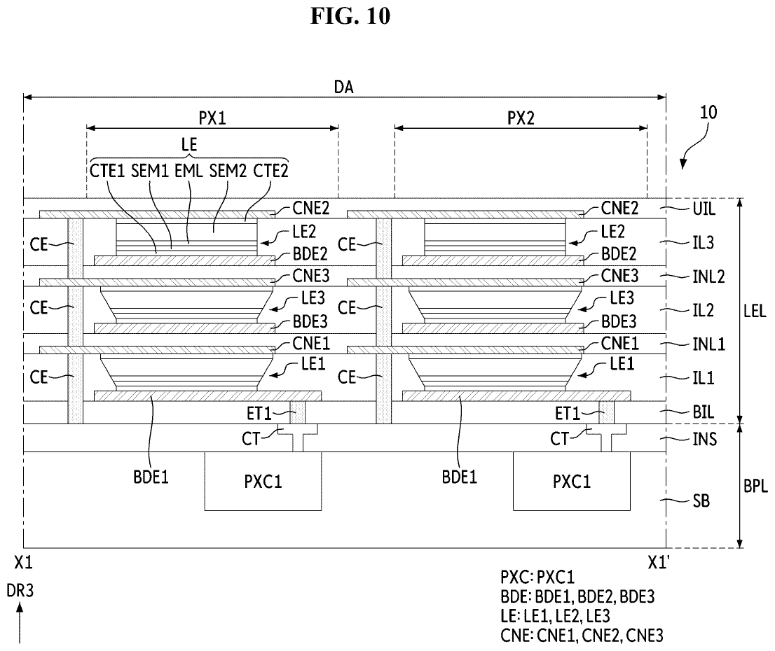

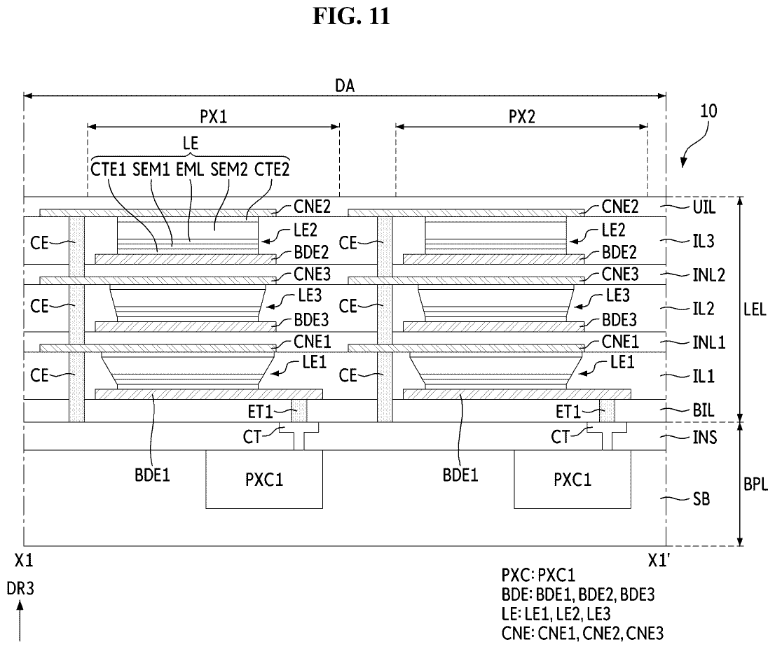

FIG. 9 is a cross-sectional view illustrating an embodiment of a display device. FIG. 10 is a cross-sectional view showing an embodiment of a display device. FIG. 11 is a cross-sectional view showing an embodiment of a display device. FIGS. 9, 10, and 11 illustrate embodiments of a cross-section of a portion of the display area DA corresponding to line X1-X1′ of FIG. 2, for example. FIGS. 9, 10, and 11 illustrate embodiments that differ from the embodiments of FIGS. 4, 7, and 8, respectively, with respect to the arrangement direction or cross-sectional shape of the light-emitting elements LE.

Referring to FIGS. 9, 10, and 11, the light-emitting elements LE including inclined sidewalls may have a reverse-tapered cross-sectional shape. In an embodiment, the first light-emitting elements LE1 and/or the third light-emitting elements LE3 may be etched to include inclined sidewalls before being bonded to the lower substrate BPL, and then bonded or disposed on the lower substrate BPL such that the first contact electrodes CTE1 (or the first semiconductor layers SEM1) are connected to the respective electrodes BDE.

In an embodiment, the first semiconductor layer SEM1 of each light-emitting element LE may be a p-type semiconductor layer and may be electrically connected to the first pixel electrode ET1, the second pixel electrode ET2, or the third pixel electrode ET3. Additionally, the second semiconductor layer SEM2 of each light-emitting element LE may be an n-type semiconductor layer, and may be electrically connected to the common electrode CE. In this case, the display device 10 may be formed in a common cathode structure.

In another embodiment, the first semiconductor layer SEM1 of each light-emitting element LE may be an n-type semiconductor layer and may be electrically connected to the first pixel electrode ET1, the second pixel electrode ET2, or the third pixel electrode ET3. Additionally, the second semiconductor layer SEM2 of each light-emitting element LE may be a p-type semiconductor layer, and may be electrically connected to the common electrode CE. In this case, the display device 10 may be formed in a common anode structure.

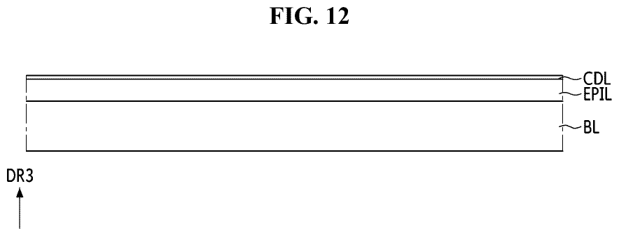

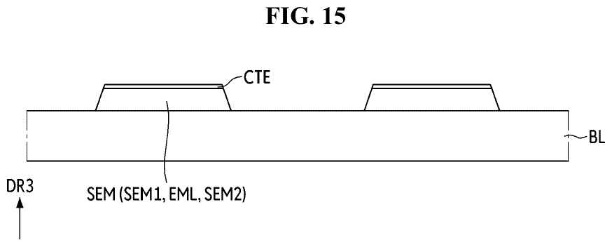

FIGS. 12 to 16 are cross-sectional views illustrating a method of manufacturing a display device including light-emitting elements. FIGS. 12 to 16 illustrate an embodiment of the steps of forming the light-emitting elements LE including inclined sidewalls or vertical sidewalls among the manufacturing steps of the display device 10 including the light-emitting elements LE, for example.

Referring to FIG. 12, an epi-layer EPIL may be formed or disposed on a base substrate BL. In an embodiment, a conductive layer CDL for forming a contact electrode (e.g., the first contact electrode CTE1 or the second contact electrode CTE2) may be further formed on the epi-layer EPIL.

The base substrate BL may be a semiconductor substrate for forming the epi-layer EPIL, or may be the lower substrate BPL onto which the epi-layer EPIL is bonded or transferred. In an embodiment, the epi-layer EPIL may be etched on a semiconductor substrate on which the epi-layer EPIL has been grown, or the epi-layer EPIL may be etched after being disposed on the lower substrate BPL by a bonding process (e.g., a wafer-to-wafer bonding process) or the like, for example.

In an embodiment, when the base substrate BL is a semiconductor substrate for forming the epi-layer EPIL, the base substrate BL may be a growth substrate suitable for epitaxial growth. In an embodiment, the base substrate BL may include a material such as GaAs, silicon (Si), sapphire, SiC, GaN, or ZnO, for example. In an embodiment, the base substrate BL may be a silicon or sapphire substrate. When the epitaxial growth of the epi-layer EPIL for manufacturing the light-emitting elements LE may be smoothly achieved, the type or material of the base substrate BL is not particularly limited.

In another embodiment, when the base substrate BL is the lower substrate BPL (or a substrate including a plurality of cell regions for simultaneously forming the plurality of display devices 10) of the display device 10, at least one insulating layer, the pixel electrodes ET and/or the common electrode CE to be connected to the light-emitting elements LE, the electrodes BDE (or a bonding layer for forming the electrodes BDE) disposed below the light-emitting elements LE, and/or the first contact electrodes CTE1 (or a conductive layer for forming the first contact electrodes CTE1) of the light-emitting elements LE may be disposed between the lower substrate BPL and the epi-layer EPIL.

The epi-layer EPIL may include semiconductor layers for forming the first semiconductor layers SEM1, the light-emitting layers EML, and the second semiconductor layers SEM2 of the first light-emitting elements LE1, the second light-emitting elements LE2, or the third light-emitting elements LE3. In an embodiment, the epi-layer EPIL may be formed as multiple layers including a first epi-layer, a second epi-layer, and a third epi-layer for forming the first semiconductor layers SEM1, the light-emitting layers EML, and the second semiconductor layers SEM2 of the first light-emitting elements LE1, the second light-emitting elements LE2, or the third light-emitting elements LE3, for example.

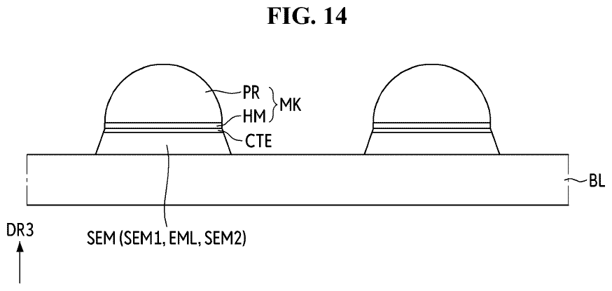

The conductive layer CDL may include or consist of a conductive material for forming the first contact electrodes CTE1 or the second contact electrodes CTE2 of the first light-emitting elements LE1, the second light-emitting elements LE2, or the third light-emitting elements LE3. Depending on the arrangement direction of the light-emitting elements LE in the light-emitting element layer LEL, contact electrodes (e.g., the contact electrodes CTE in FIG. 14) formed from the conductive layer CDL may become the first contact electrodes CTE1 disposed on the respective electrodes BDE or the second contact electrodes CTE2 connected to the respective connection electrodes CNE.

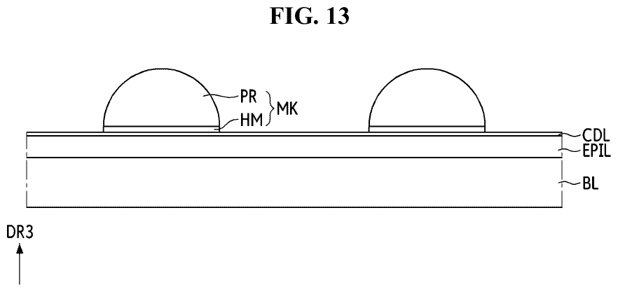

Referring to FIGS. 13 to 15, by disposing a mask MK on the conductive layer CDL and etching the epi-layer EPIL and the conductive layer CDL, semiconductor layers SEM and the contact electrodes CTE of the first light-emitting elements LE1, the second light-emitting elements LE2, or the third light-emitting elements LE3 may be formed. The mask MK may have a size and shape corresponding to the size and shape of the light-emitting elements LE to be formed. In an embodiment, the mask MK may include a hard mask HM and a photoresist pattern PR, but is not limited thereto. In an embodiment, the epi-layer EPIL and the conductive layer CDL may be etched by a dry etching process using the mask MK. The mask MK may be removed after the etching of the epi-layer EPIL and the conductive layer CDL is completed.

In an embodiment, the light-emitting elements LE including inclined sidewalls, such as the first light-emitting elements LE1, may be manufactured or formed in an etched shape using the mask MK. In an embodiment, the light-emitting elements LE including vertical sidewalls, such as the second light-emitting elements LE2, may be manufactured or formed through an additional process.

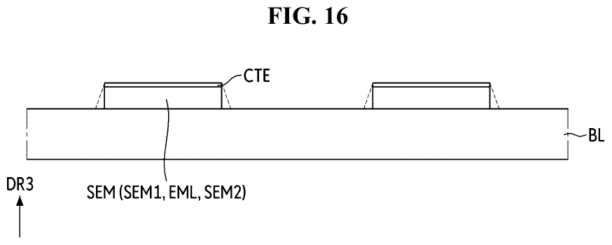

Referring to FIG. 16, the light-emitting elements LE including vertical sidewalls may be manufactured or formed to include substantially vertical sidewalls through an additional process such as wet treatment. Accordingly, the surfaces (e.g., side surfaces) of the light-emitting elements LE that have been damaged by exposure to plasma during an etching process of the epi-layer EPIL may be refined, and surface defects of the light-emitting elements LE may be reduced.

In an embodiment, when the light-emitting elements LE are etched on a semiconductor substrate on which the epi-layer EPIL is formed, the light-emitting elements LE may be disposed (e.g., bonded) on the lower substrate BPL, and a pixel process for connecting the light-emitting elements LE to the pixel electrodes ET and the common electrode CE may then be performed. In another embodiment, when the light-emitting elements LE are etched on the lower substrate BPL, a subsequent pixel process for forming an insulating layer that covers the light-emitting elements LE or electrodes (e.g., the connection electrodes CNE and/or the common electrode CE) connected to the light-emitting elements LE may be performed. Accordingly, the display device 10 in the embodiments described above may be manufactured.

In case that the first light-emitting elements LE1, the second light-emitting elements LE2, and the third light-emitting elements LE3 are disposed in different layers on the lower substrate BPL, the respective pixel processes (e.g., bonding process and/or etching process) for forming the first light-emitting elements LE1, the second light-emitting elements LE2, and the third light-emitting elements LE3 may be performed sequentially or continuously. In an embodiment, after a pixel process for disposing or forming the first light-emitting elements LE1 on the lower substrate BPL has been performed, a pixel process for disposing or forming the third light-emitting elements LE3 on the first light-emitting elements LE1 may be performed, for example. Further, after disposing or forming the third light-emitting elements LE3 on the first light-emitting elements LE1, a pixel process for disposing or forming the second light-emitting elements LE2 on the third light-emitting elements LE3 may be performed sequentially or continuously.

As described above, according to the display device 10 and its manufacturing method in embodiments, the light-emitting elements LE that are disposed in different layers in the light-emitting element layer LEL and emit light of different colors may have differentiated shapes or structures. In an embodiment, among the first light-emitting element LE1, the second light-emitting element LE2, and the third light-emitting element LE3, the first light-emitting element LE1, which is relatively insensitive to surface defects, may be formed to include an inclined sidewall, thereby preventing or reducing area or volume loss of the light-emitting layer EML, for example. Additionally, among the first light-emitting element LE1, the second light-emitting element LE2, and the third light-emitting element LE3, the second light-emitting element LE2, which is relatively sensitive to surface defects, may undergo an additional process such as wet treatment to reduce surface defects and, as a result, may be formed to include a vertical sidewall. The third light-emitting element LE3 may include an inclined sidewall or a vertical sidewall.

By embodiments, the shape or structure of the light-emitting elements LE may be differentiated based on or corresponding to the characteristics of the light-emitting elements LE. As a result, the efficiency of the light-emitting elements LE may be improved or optimized, and the light efficiency of the light-emitting elements LE and the pixel PX including the light-emitting elements LE may be improved.

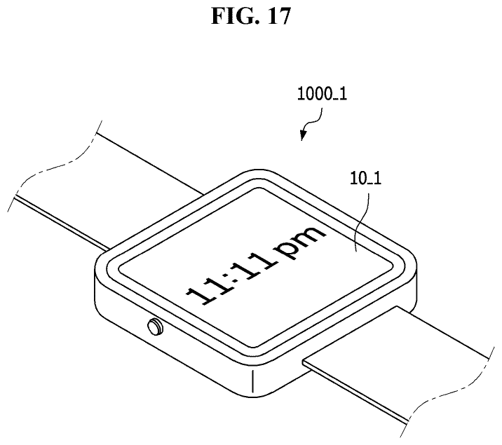

FIG. 17 is a diagram illustrating an embodiment of an electronic device such as a smart watch including a display device.

Referring to FIG. 17, a display device 10_1 in an embodiment may be applied to an electronic device (e.g., a smart watch 1000_1) that is one of the smart devices.

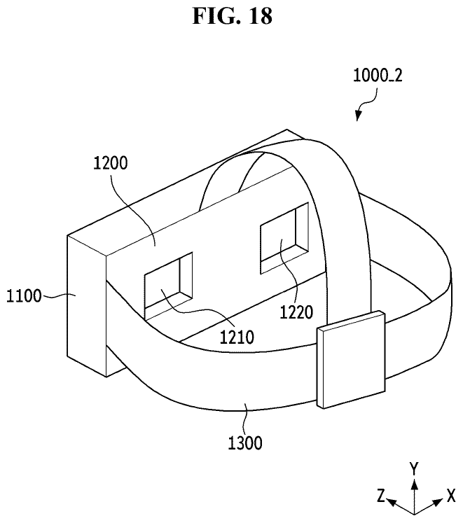

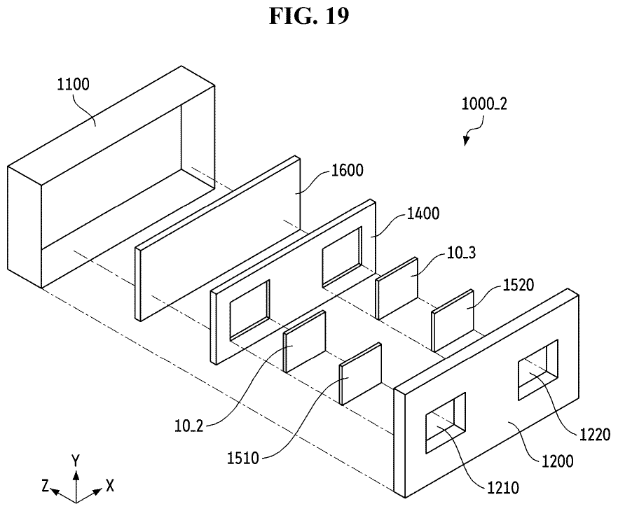

FIGS. 18 and 19 illustrate an embodiment of an electronic device such as a head mounted display including a display device.

Referring to FIGS. 18 and 19, an electronic device (e.g., a head mounted display 1000_2) in an embodiment may be a virtual reality device. The head mounted display 1000_2 includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to the user's left eye, and the second display device 10_3 provides an image to the user's right eye.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and between the second display device 10_3 and the control circuit board 1600. The middle frame 1400 serves to support and fix the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through the connector. The control circuit board 1600 may convert an image source inputted from the outside into video data, and transmit the video data to the first display device 10_2 and the second display device 10_3 through the connector.

The control circuit board 1600 may transmit the video data corresponding to a left-eye image optimized for the user's left eye to the first display device 10_2, and may transmit the video data corresponding to a right-eye image optimized for the user's right eye to the second display device 10_3. In an alternative embodiment, the control circuit board 1600 may transmit the same video data to the first display device 10_2 and the second display device 10_3.

The display device housing 1100 serves to accommodate the first display device 10_2, the second display device 10_3, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is disposed and the second eyepiece 1220 at which the user's right eye is disposed. FIGS. 18 and 19 illustrate that the first eyepiece 1210 and the second eyepiece 1220 are disposed separately, but the embodiment of the disclosure is not limited thereto. The first eyepiece 1210 and the second eyepiece 1220 may be combined into one.

The first eyepiece 1210 may be aligned with the first display device 10_2 and the first optical member 1510, and the second eyepiece 1220 may be aligned with the second display device 10_3 and the second optical member 1520. Therefore, the user may view, through the first eyepiece 1210, the image of the first display device 10_2 magnified as a virtual image by the first optical member 1510, and may view, through the second eyepiece 1220, the image of the second display device 10_3 magnified as a virtual image by the second optical member 1520.

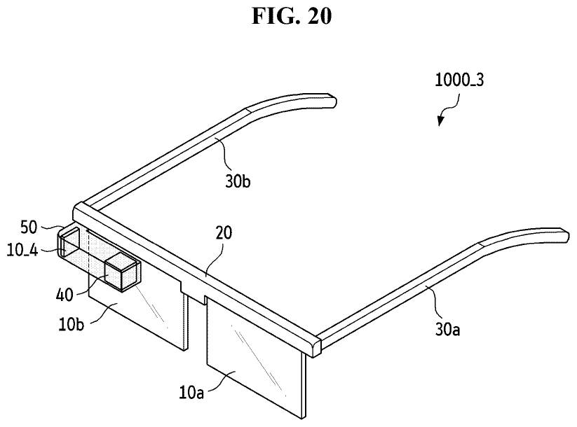

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1100 is implemented to be lightweight and compact, the head mounted display 1000_2 may be provided with an eyeglass frame as shown in FIG. 20 instead of the head mounted band 1300.

In addition, the head mounted display 1000_2 may further include a battery for supplying power, an external memory slot for accommodating an external memory, and an external connection port and a wireless communication module for receiving an image source. The external connection port may be a universe serial bus (“USB”) terminal, a display port, or a high-definition multimedia interface (HDMI) terminal, and the wireless communication module may be a 5G communication module, a 4G communication module, a Wi-Fi module, or a Bluetooth module.

FIG. 20 illustrates an embodiment of an electronic device such as a head mounted display including a display device.

Referring to FIG. 20, a head mounted display 1000_3 in an embodiment may be a glasses-type device. The head mounted display 1000_3 in an embodiment may include the display device 10_4, a left eye lens 10a, a right eye lens 10b, a support frame 20, temples 30a and 30b, a reflection member 40, and a display device housing 50.

FIG. 20 illustrates that the head-mounted display 1000_3 is an eyeglasses-type display device including eyeglass frame legs 30a and 30b, but the disclosure is not limited thereto. In an embodiment, the head-mounted display device 1000_3 may be applied in various forms in other electronic devices, for example.

The display device housing 50 may include the display device 10_4 and the reflection member 40 (or an optical path changing member). An image displayed on the display device 10_4 may be reflected by the reflection member 40 and provided to the user's right eye through the right eye lens 10b. As a result, the user may view an augmented reality image, through the right eye, in which a virtual image displayed on the display device 10_4 and a real image seen through the right eye lens 10b are combined. In an embodiment, the display device housing 50 may further include an optical member disposed between the display device 10_4 and the reflection member 40. The image displayed on the display device 10_4 may be magnified by the optical member, and may be provided to the user's right eye through the right eye lens 10b after the optical path thereof is changed by the reflection member 40.

FIG. 20 illustrates that the display device housing 50 is disposed at the end of the right side of the support frame 20, but the embodiment of the disclosure is not limited thereto. In an embodiment, the display device housing 50 may be disposed at the left end of the support frame 20, and in this case, the image displayed on the display device 10_4 may be reflected by the reflection member 40 and provided to a user's left eye through the left eye lens 10a, for example. As a result, the user may view the image displayed on the display device 10_4 with the left eye. In an alternative embodiment, the display device housing 50 may be disposed at both the left end and the right end of the support frame 20, in which case the user may view the image displayed on the display device 10_4 through both the left eye and the right eye.

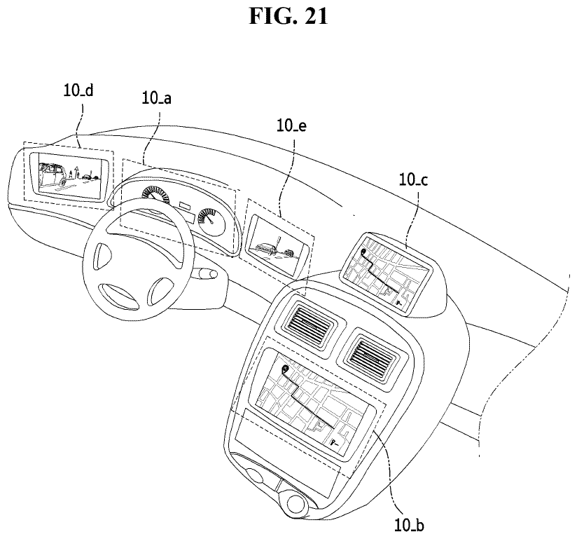

FIG. 21 is a diagram illustrating an embodiment of an electronic device such as a dashboard of an automobile and a center fascia including display devices. FIG. 21 illustrates an embodiment of a vehicle to which the display devices 10_a, 10_b, 10_c, 10_d, and 10_e are applied.

Referring to FIG. 21, the display devices 10_a, 10_b, and 10_c in an embodiment may be applied to the dashboard of the automobile, the center fascia of the automobile, or the center information display (“CID”) of the dashboard of the automobile. Further, the display devices 10_d, and 10_e in an embodiment may be applied to a room mirror display instead of side mirrors of the automobile.

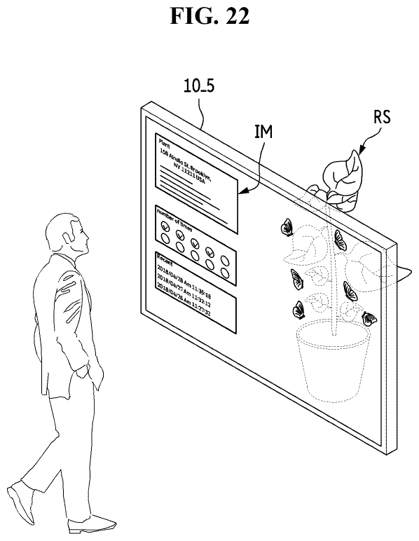

FIG. 22 is a diagram illustrating an embodiment of an electronic device a transparent display device including a display device.

Referring to FIG. 22, the display device 10_5 in an embodiment may be applied to the transparent display device. The transparent display device may display an image IM, and also may transmit light. Thus, a user disposed on the front side of the transparent display device may view an object RS or a background on the rear side of the transparent display device as well as the image IM displayed on the display device 10_5. When the display device 10_5 is applied to the transparent display device, the substrate of the display device 10_5 may include a light-transmitting portion capable of transmitting light or may include or consist of a material capable of transmitting light.

In concluding the detailed description, those skilled in the art will appreciate that many variations and modifications may be made to the embodiments without substantially departing from the principles of the invention. Therefore, the disclosed embodiments of the invention are used in a generic and descriptive sense only and not for purposes of limitation.

What is claimed is:

1. A display device comprising:
a lower substrate;
a first electrode disposed on the lower substrate;
a first light-emitting element disposed on the first electrode and including a first sidewall and a first bottom surface;
a second electrode disposed on the first light-emitting element; and
a second light-emitting element disposed on the second electrode and including a second sidewall and a second bottom surface,
wherein a first angle between the first sidewall and the first bottom surface is different from a second angle between the second sidewall and the second bottom surface.

2. The display device of claim 1, wherein the first electrode, the first light-emitting element, the second electrode, and the second light-emitting element overlap each other in a plan view.

3. The display device of claim 1, wherein one of the first and second sidewalls comprises an inclined sidewall having a taper angle, and
the remaining one of the first and second sidewalls comprises a vertical sidewall.

4. The display device of claim 3, wherein one of the first and second angles between one of the first and second bottom surfaces and the one of the first and second sidewalls comprising the inclined sidewall is less than 85° or greater than 95°, and
a remaining one of the first and second angles between a remaining one of the first and second bottom surfaces and the remaining one of the first and second sidewalls comprising the vertical sidewall is in a range of 85° to 95°.

5. The display device of claim 3, wherein the first light-emitting element emits red light,
the second light-emitting element emits blue light or green light,
the first sidewall comprises the inclined sidewall, and
the second sidewall comprises the vertical sidewall.

6. The display device of claim 3, wherein the first light-emitting element and the second light-emitting element comprise first and second light-emitting layers including indium at different contents, respectively, and
an indium content of the first light-emitting layer of the first light-emitting element is higher than an indium content of the second light-emitting layer of the second light-emitting element,
the first sidewall comprises the inclined sidewall, and
the second sidewall comprises the vertical sidewall.

7. The display device of claim 3, wherein in a plan view, one of the first and second light-emitting elements comprising the one of the first and second sidewalls comprising the inclined sidewall is larger than a remaining one of the first and second light-emitting elements comprising the remaining one of the first and second sidewalls comprising the vertical sidewall.

8. The display device of claim 1, further comprising:
a third electrode disposed between the first light-emitting element and the second electrode; and
a third light-emitting element disposed on the third electrode and disposed between the first light-emitting element and the second light-emitting element, and
wherein the third light-emitting element comprises a third sidewall having a third angle equal to the first angle or the second angle.

9. The display device of claim 1, further comprising:
a third electrode disposed between the first light-emitting element and the second electrode; and
a third light-emitting element disposed on the third electrode and disposed between the first light-emitting element and the second light-emitting element, and
wherein the first angle defined between the first bottom surface and the first sidewall of the first light-emitting element, the second angle defined between the second bottom surface and the second sidewall of the second light-emitting element, and a third angle defined between a third bottom surface and a third sidewall of the third light-emitting element are different from each other.

10. The display device of claim 9, wherein the third angle has a value between the first angle and the second angle.

11. A display device comprising:
a lower substrate; and
a plurality of light-emitting elements disposed on the lower substrate, and overlapping each other in a plan view, the plurality of light-emitting elements comprising:
a first light-emitting element comprising a first sidewall and a first bottom surface; and
a second light-emitting element comprising a second sidewall and a second bottom surface,
wherein a first angle between the first sidewall and the first bottom surface is different from a second angle between the second sidewall and the second bottom surface.

12. The display device of claim 11, wherein the first sidewall comprises an inclined sidewall which is inclined at the first angle in a range of less than 85° or greater than 95° with respect to the first bottom surface of the first light-emitting element, and
the second sidewall comprises a vertical sidewall having the second angle in a range of 85° to 95° with respect to the second bottom surface of the second light-emitting element.

13. The display device of claim 11, further comprising a plurality of electrodes respectively disposed below the plurality of light-emitting elements and overlapping each other in the plan view.

14. The display device of claim 13, further comprising:
a plurality of pixel electrodes disposed between the lower substrate and the plurality of electrodes and individually connected to the plurality of electrodes;
connection electrodes respectively disposed on top of the plurality of light-emitting elements; and
a common electrode electrically connected to the connection electrodes.

15. The display device of claim 11, wherein the first light-emitting element and the second light-emitting element emit light of different colors.

16. An electronic device comprising:
a display device comprising:
a lower substrate;
a first electrode disposed on the lower substrate;
a first light-emitting element disposed on the first electrode and comprising a first sidewall and a first bottom surface;
a second electrode disposed on the first light-emitting element and comprising a second sidewall and a second bottom surface; and
a second light-emitting element disposed on the second electrode,
wherein a first angle between the first sidewall and the first bottom surface is different from a second angle between a second sidewall and the second bottom surface.

17. The electronic device of claim 16, wherein the first electrode, the first light-emitting element, the second electrode, and the second light-emitting element overlap each other in a plan view.

18. The electronic device of claim 16, wherein one of the first and second sidewalls comprises an inclined sidewall having a taper angle, and
the remaining one of the first and second sidewalls comprises a vertical sidewall.

19. The electronic device of claim 18, wherein one of the first and second angles between one of the first and second bottom surfaces and the one of the first and second sidewalls comprising the inclined sidewall is less than 85° or greater than 95°, and
a remaining one of the first and second angles between a remaining one of the first and second bottom surfaces and the remaining one of the first and second sidewalls comprising the vertical sidewall is in a range of 85° to 95°.

20. The electronic device of claim 18, wherein the first light-emitting element emits red light,
the second light-emitting element emits blue light or green light,
the first sidewall comprises the inclined sidewall, and
the second sidewall comprises the vertical sidewall.
